(19) United States
(12) Patent Application Publication
(10) Pub. No.: US 2025/0151397 A1
(43) Pub. Date: May 8, 2025

(54) DISPLAY PANEL AND DISPLAY DEVICE

(71) Applicants: BOE TECHNOLOGY GROUP CO., LTD., Beijing (CN); CHENGDU BOE OPTOELECTRONICS TECHNOLOGY CO., LTD., Sichuan (CN)

(72) Inventor: Meng LI, Beijing (CN)

(21) Appl. No.: 18/832,075

(22) PCT Filed: Aug. 31, 2022
(86) PCT No.: PCT/CN2022/116185

§ 371 Date: Jul. 22, 2024

(51) Int. Cl. H10D 86/40; G09G 3/32; H10D 86/60

(52) U.S. Cl. CPC H10D 86/441; H10D 86/481; H10D 86/60; G09G 3/32; G09G 2300/0426; G09G 2300/0819; G09G 2300/0842; G09G 2300/0861; G09G 2310/08; G09G 2320/0247

(57) ABSTRACT

A display panel and a display device are provided. The display panel includes a pixel driving circuit, a base substrate, a first reset signal line, a second gate line and a first conductive portion. The orthographic projection of the second gate line on the base substrate is located between the orthographic projection of the first reset signal line on the base substrate and an orthographic projection of the first conductive portion on the base substrate.

### TECHNICAL FIELD

The present disclosure relates to the display technical field, and in particular, to a display panel and a display device.

### BACKGROUND

In related art, a display panel usually includes a pixel driving circuit and a light-emitting unit. The pixel driving circuit is used to drive the light-emitting unit to emit light. The pixel driving circuit includes a driving transistor that provides a driving current to the light-emitting unit according to its gate voltage. However, the gate electrode of the driving transistor has a leakage problem, causing display abnormalities.

It should be noted that the information disclosed in the above background section is only used to enhance understanding of the background of the present disclosure, and therefore may include information that does not constitute prior art known to those of ordinary skill in the art.

### SUMMARY

According to an aspect of the present disclosure, there is provided a display panel. The display panel includes: a pixel driving circuit, wherein the pixel driving circuit includes a driving transistor, a first transistor and a second transistor, a first electrode of the second transistor is connected to a gate electrode of the driving transistor, a second electrode of the second transistor is connected to a second electrode of the driving transistor, a first electrode of the first transistor is connected to a first initialization signal line, and a second electrode of the first transistor is connected to the second electrode of the second transistor. The display panel further includes: a base substrate, a first reset signal line, a second gate line, and a first conductive portion. An orthographic projection of the first reset signal line on the base substrate extends along a first direction, and a partial structure of the first reset signal line is used to form a gate electrode of the first transistor. An orthographic projection of the second gate line on the base substrate extends along the first direction, and a partial structure of the second gate line is used to form a gate electrode of the second transistor. The first conductive portion is used to form the gate electrode of the driving transistor. The orthographic projection of the second gate line on the base substrate is located between the orthographic projection of the first reset signal line on the base substrate and an orthographic projection of the first conductive portion on the base substrate.

In an example embodiment of the present disclosure, the display panel further includes: a first active portion, a second active portion, a seventeenth active portion, a twentieth active portion and a fifth bridge portion. The orthographic projection of the first reset signal line on the base substrate covers an orthographic projection of the first active portion on the base substrate, and the first active portion is used to form a channel region of the first transistor. The orthographic projection of the second gate line on the base substrate covers an orthographic projection of the second active portion on the base substrate, and the second active portion is used to form a channel region of the second transistor. The seventeenth active portion is connected to the first active portion. The twentieth active portion is connected to the second active portion. An orthographic projection of the fifth bridge portion on the base substrate extends along a second direction, the second direction intersects the first direction, and the fifth bridge portion is connected to the seventeenth active portion and the twentieth active portion through via holes respectively, and the orthographic projection of the fifth bridge portion on the base substrate intersects the orthographic projection of the second gate line on the base substrate.

In an example embodiment of the present disclosure, the display panel further includes: a first active portion, a seventeenth active portion, a third active portion, an eighteenth active portion and a fifth bridge portion. The orthographic projection of the first reset signal line on the base substrate covers an orthographic projection of the first active portion on the base substrate, and the first active portion is used to form a channel region of the first transistor. The seventeenth active portion is connected to the first active portion. The orthographic projection of the first conductive portion on the base substrate covers an orthographic projection of the third active portion on the base substrate, and the third active portion is used to form a channel region of the driving transistor. The eighteenth active portion is connected to the third active portion. An orthographic projection of the fifth bridge portion on the base substrate extends along a second direction, the second direction intersects the first direction, the fifth bridge portion is connected to the seventeenth active portion and the eighteenth active portion through via holes, respectively, and the orthogonal projection of the fifth bridge portion on the base substrate intersects the orthogonal projection of the second gate line on the base substrate.

In an example embodiment of the present disclosure, the display panel further includes: a nineteenth active portion and a fourth bridge portion. The nineteenth active portion is connected to a side of the second active portion away from the twentieth active portion. The fourth bridge portion is connected to the nineteenth active portion and the first conductive portion through via holes, respectively. An orthographic projection of the fourth bridge portion on the base substrate extends along the second direction and intersects the orthographic projection of the second gate line on the base substrate.

In an example embodiment of the present disclosure, the display panel further includes: a first active layer, a first conductive layer, a second active layer, a third conductive layer and a fourth conductive layer. The first active layer is located at a side of the base substrate, wherein the first active layer includes a first active portion, a third active portion, a seventeenth active portion and an eighteenth active portion, the first active portion is used to form a channel region of the first transistor, the third active portion is used to form a channel region of the driving transistor, the seventeenth active portion is connected to the first active portion, and the eighteenth active portion is connected to the third active portion. The first conductive layer is located at a side of the first active layer away from the base substrate, wherein the first conductive layer includes the first reset signal line and the first conductive portion. The second active layer is located at a side of the first conductive layer away from the base substrate, wherein the second active layer includes a second active portion, a nineteenth active portion and a twentieth active portion, the second active portion is used to form a channel region of the second transistor, and the nineteenth active portion and the twentieth active portion are respectively connected to both ends of the second active portion. The third conductive layer is located at a side of the second active layer away from the base substrate, wherein the third conductive layer includes the second gate line. The fourth conductive layer is located at a side of the third conductive layer away from the base substrate, wherein the fourth conductive layer includes a fourth bridge portion and a fifth bridge portion, the fourth bridge portion is connected to the nineteenth active portion and the first conductive portion through via holes, respectively, and the fifth bridge portion is connected to the eighteenth active portion, the seventeenth active portion and the twentieth active portion through via holes, respectively.

In an example embodiment of the present disclosure, the pixel driving circuit further includes a fourth transistor, a first electrode of the fourth transistor is connected to a data line, and a second electrode of the fourth transistor is connected to a first electrode of the driving transistor. The display panel further includes: a first active layer and a second active layer. The first active layer is located at a side of the base substrate, wherein the first active layer includes a third active portion and a fourth active portion, the third active portion is used to form a channel region of the driving transistor, and the fourth active portion is used to form a channel region of the fourth transistor. The second active layer is located at a side of the first active layer away from the base substrate, wherein the second active layer includes a second active portion, the orthographic projection of the second gate line on the base substrate covers an orthographic projection of the second active portion on the base substrate, and the second active portion is used to form a channel region of the second transistor. In the first direction, an orthographic projection of the third active portion on the base substrate is located between the orthographic projection of the second active portion on the base substrate and an orthographic projection of the fourth active portion on the base substrate.

In an example embodiment of the present disclosure, the pixel driving circuit further includes a fourth transistor, a first electrode of the fourth transistor is connected to a data line, and a second electrode of the fourth transistor is connected to a first electrode of the driving transistor. The display panel further includes a first conductive layer. The first conductive layer is located at a side of the base substrate, wherein the first conductive layer includes a first gate line, an orthographic projection of the first gate line on the base substrate extends along the first direction, and the orthographic projection of the first gate line on the base substrate is located between the orthographic projection of the first reset signal line on the base substrate and the orthographic projection of the second gate line on the base substrate, and a partial structure of the first gate line is used to form a gate electrode of the fourth transistor. An orthographic projection of the nineteenth active portion on the base substrate at least partially overlaps with the orthographic projection of the first gate line on the base substrate.

In an example embodiment of the present disclosure, a maximum size of the orthographic projection of the nineteenth active portion on the base substrate in the first direction is larger than a maximum size of the orthographic projection of the nineteenth active portion on the base substrate in the second direction.

In an example embodiment of the present disclosure, the maximum size of the orthographic projection of the nineteenth active portion on the base substrate in the first direction is L1, the maximum size of the orthographic projection of the nineteenth active portion on the base substrate in the second direction is L2, and L1/L2 is greater than or equal to 1.5 and less than or equal to 5.

In an example embodiment of the present disclosure, the pixel driving circuit further includes a fourth transistor, a first electrode of the fourth transistor is connected to a data line, a second electrode of the fourth transistor is connected to a first electrode of the driving transistor, and a gate electrode of the fourth transistor is connected to a first gate line;

wherein a capacitance formed by an equipotential structure of the first conductive portion and an equipotential structure of the first gate line is C1, a capacitance formed by the equipotential structure of the first conductive portion and an equipotential structure of the second gate line is C2, and C1 is greater than C2.

In an example embodiment of the present disclosure, the display panel further includes: a second active portion, a nineteenth active portion, and a fourth bridge portion. The second active portion is used to form a channel region of the second transistor. The nineteenth active portion is connected to the second active portion, wherein an orthographic projection of the nineteenth active portion on the base substrate at least partially overlaps with an orthographic projection of the first gate line on the base substrate. The fourth bridge portion is connected to the nineteenth active portion and the first conductive portion through via holes respectively, and an orthogonal projection of the fourth bridge portion on the base substrate extends along a second direction and at least partially overlaps with the orthographic projection of the second gate line on the base substrate. An overlapping area of the orthographic projection of the nineteenth active portion on the base substrate and the orthographic projection of the first gate line on the base substrate is S1, and an overlapping area of the orthographic projection of the fourth bridge portion on the base substrate and the orthographic projection of the second gate line on the base substrate is S2; S1/S2 is greater than or equal to 1.2 and less than or equal to 2.

In an example embodiment of the present disclosure, the display panel further includes a light-emitting unit, the pixel driving circuit is used to drive the light-emitting unit to emit light, the pixel driving circuit further includes a seventh transistor, a first electrode of the seventh transistor is connected to a second initialization signal line, and a second electrode of the seventh transistor is connected to a first electrode of the light-emitting unit. The display panel further includes: a fourth conductive layer. The fourth conductive layer is located at a side of the base substrate, wherein the fourth conductive layer includes the second initialization signal line. The second initialization signal line includes a first initialization signal sub-line and a second initialization signal sub-line, an orthographic projection of the first initialization signal sub-line on the base substrate extends along the first direction, an orthographic projection of the second initialization signal sub-line on the base substrate extends along a second direction, and the second direction intersects the first direction. The first initialization signal sbu-line is connected to the second initialization signal sub-line whose orthographic projection on the base substrate intersects the orthographic projection of the first initialization signal sub-line on the base substrate.

In an example embodiment of the present disclosure, the pixel driving circuit further includes a fifth transistor, a first electrode of the fifth transistor is connected to a power line, and a second electrode is connected to a first electrode of the driving transistor. The display panel further includes: a fourth conductive layer and a fifth conductive layer. The fifth conductive layer is located at a side of the fourth conductive layer away from the base substrate. The fifth conductive layer includes the power line. A first notch is formed in the power line, and the first notch is at least partially located in a light-transmitting region of the display panel.

In an example embodiment of the present disclosure, an orthographic projection of the power line on the base substrate extends along a second direction, and the second direction intersects the first direction. The power line includes a first power line segment, a second power line segment and a third power line segment, and the second power line segment is connected between the first power line segment and the third power line segment. A size of an orthographic projection of the second power line segment on the base substrate in the first direction is larger than a size of an orthogonal projection of the first power line segment on the base substrate in the first direction, the size of the orthographic projection of the second power line segment on the base substrate in the first direction is larger than a size of an orthogonal projection of the third power line segment on the base substrate in the first direction. The first notch includes a first side and a second side, and an orthographic projection of the first side on the base substrate and an orthographic projection of the second side on the base substrate form an angle less than 90°. The first side is formed by a part of an edge of the second power line segment, and the second side is formed by a part of an edge of the first power line segment.

In an example embodiment of the present disclosure, the pixel driving circuit further includes a capacitor, a first electrode of the capacitor is connected to the gate electrode of the driving transistor, a second electrode of the capacitor is connected to a power line, and the first conductive portion is reused as the first electrode of the capacitor. The display panel further includes: a first conductive layer, a second active layer, and a second conductive layer. The first conductive layer is located at a side of the base substrate. The second active layer is located at a side of the first conductive layer away from the base substrate. The second conductive layer is located between the first conductive layer and the second active layer, wherein the second conductive layer includes a second conductive portion, an orthographic projection of the second conductive portion on the base substrate at least partially overlaps with the orthographic projection of the first conductive portion on the base substrate, and the second conductive portion is used to form the second electrode of the capacitor. At least a part of second conductive portions adjacent in the first direction are connected.

In an example embodiment of the present disclosure, the display panel includes repeating units distributed in an array along the first direction and the second direction, the first direction intersects the second direction, and the repeating unit includes two pixel driving circuits distributed in the first direction, and two pixel driving circuits in a same repeating unit are arranged at least partially in mirror symmetry. The second conductive layer further includes: a first connection portion. The first connection portion is connected between two second conductive portions in a same repeating unit, and a size of an orthogonal projection of the first connection portion on the base substrate in the second direction is smaller than a size of an orthographic projection of the second conductive portion on the base substrate in the second direction, and the first connection portion and a second conductive portion connected thereto form a third notch. An orthographic projection of the third notch on the base substrate at least partially overlaps with an orthographic projection of an equipotential structure of the second electrode of the driving transistor on the base substrate.

In an example embodiment of the present disclosure, the display panel includes repeating units distributed in an array along the first direction and the second direction, the first direction intersects the second direction intersect, the repeating unit includes two pixel driving circuits distributed in the first direction, and two pixel driving circuits in a same repeating unit are arranged at least partially in mirror symmetry. Multiple second gate lines are connected to a same signal terminal. The second conductive layer further includes: a second connection portion connected between two adjacent second conductive portions in repeating units which are adjacent in the first direction, and a size of an orthographic projection of the second connection portion on the base substrate in the second direction is smaller than a size of an orthogonal projection of the second conductive portion on the base substrate in the second direction, and the second connection portion and a second conductive portion connected thereto form a second notch. An orthographic projection of the second notch on the base substrate at least partially overlaps with an orthographic projection of an equipotential structure of the first electrode of the driving transistor on the base substrate.

In an example embodiment of the present disclosure, the display panel further includes a light-emitting unit, the pixel driving circuit is used to drive the light-emitting unit to emit light, the pixel driving circuit further includes a seventh transistor and an eighth transistor, a first electrode of the seventh transistor is connected to a second initialization signal line, a second electrode of the seventh transistor is connected to a first electrode of the light-emitting unit, a first electrode of the eighth transistor is connected to a third initialization signal line, and a second electrode of the eighth transistor is connected to a first electrode of the driving transistor. The display panel further includes: a first conductive layer and a third conductive layer. The first conductive layer is located at a side of the base substrate, wherein the first conductive layer includes a second reset signal line, an orthographic projection of the second reset signal line on the base substrate extends along the first direction, and a partial structure of the second reset signal line is used to form the gate electrode of the seventh transistor. The third conductive layer is located at a side of the first conductive layer away from the base substrate, wherein the third conductive layer includes a third initialization signal line, and an orthographic projection of the third initialization signal line on the base substrate extends along the first direction. The orthographic projection of the second reset signal line on the base substrate at least partially overlaps with the orthographic projection of the third initialization signal line on the base substrate.

In an example embodiment of the present disclosure, the display panel further includes a light-emitting unit, the pixel driving circuit is used to drive the light-emitting unit to emit light, and the pixel driving circuit further includes: a fourth transistor, a fifth transistor, a sixth transistor, a seventh transistor, an eighth transistor and a capacitor. A first electrode of the fourth transistor is connected to a data line, and a second electrode of the fourth transistor is connected to a first electrode of the driving transistor. A first electrode of the fifth transistor is connected to a power line, and a second electrode of the fifth transistor is connected to the first electrode of the driving transistor. A first electrode of the sixth transistor is connected to a second electrode of the driving transistor, and a second electrode of the sixth transistor is connected to a first electrode of the light-emitting unit. A first electrode of the seventh transistor is connected to a second initialization signal line, and a second electrode of the seventh transistor is connected to the first electrode of the light-emitting unit. A first electrode of the eighth transistor is connected to a third initialization signal line, and a second electrode of the eighth transistor is connected to the first electrode of the driving transistor. The capacitor is connected between the gate electrode of the driving transistor and the power line. The display panel further includes: a first active layer, a first conductive layer, a second active layer and a third conductive layer. The first active layer includes a first active portion, a third active portion, a fourth active portion, a fifth active portion, a sixth active portion, a seventh active portion and an eighth active portion, the first active portion is used to form a channel region of the first transistor, the third active portion is used to form a channel region of the driving transistor, the fourth active portion is used to form a channel region of the fourth transistor, the fifth active portion is used to form a channel region of the fifth transistor, the sixth active portion is used to form a channel region of the sixth transistor, the seventh active portion is used to form a channel region of the seventh transistor, and the eighth active portion is used to form a channel region of the eighth transistor. The first conductive layer is located at a side of the first active layer away from the base substrate, wherein the first conductive layer includes the first reset signal line, the first gate line, the second reset signal line, an enable signal line and the first conductive portion, a partial structure of the first gate line is used to form a gate electrode of the fourth transistor, a partial structure of the enable signal line is used to form gate electrodes of the fifth transistor and the six transistor, and a partial structure of the second reset signal line is used to form gate electrodes of the seventh transistor and the eighth transistor. The second active layer is located at a side of the first conductive layer away from the base substrate, wherein the second active layer includes a second active portion, and the second active portion is used to form a channel region of the second transistor. The third conductive layer is located at a side of the second active layer away from the base substrate, wherein the third conductive layer includes the second gate line. An orthographic projection of the enable signal line on the base substrate extends along the first direction and is located at a side of the orthographic projection of the first conductive portion on the base substrate away from the orthographic projection of the first reset signal line on the base substrate. The orthographic projection of the first gate line on the base substrate extends along the first direction and is located between the orthographic projection of the second gate line on the base substrate and the orthographic projection of the first reset signal line on the base substrate. The orthographic projection of the second reset signal line on the base substrate extends along the first direction and is located at a side of the orthographic projection of the enable signal line on the base substrate away from the orthographic projection of the first conductive portion on the base substrate.

In an example embodiment of the present disclosure, the first transistor, the driving transistor, the fourth transistor, the fifth transistor, the sixth transistor, the seventh transistor and the eighth transistor are P-type transistors, and the second transistor is an N-type transistor.

According to an aspect of the present disclosure, there is provided a display device, wherein the display device includes the display panel described above.

It should be understood that the foregoing general description and the following detailed description are exemplary and explanatory only, and do not limit the present disclosure.

### BRIEF DESCRIPTION OF THE DRAWINGS

The accompanying drawings, which are incorporated in and constitute a part of the specification, illustrate embodiments consistent with the present disclosure and together with the specification, serve to explain the principles of the present disclosure. Obviously, the drawings in the following description are only some embodiments of the present disclosure. For those of ordinary skill in the art, other drawings can be obtained based on these drawings without exerting creative efforts.

FIG. 1 is a schematic circuit structure diagram of a pixel driving circuit in a display panel according to an example embodiment of the present disclosure;

FIG. 2 is a timing diagram illustrating signals on each node in the pixel driving circuit shown in FIG. 1;

FIG. 3 is a structural layout of a display panel in an example embodiment of the present disclosure;

FIG. 4 is a structural layout of a shielding layer in FIG. 3;

FIG. 5 is a structural layout of a first active layer in FIG. 3;

FIG. 6 is a structural layout of a first conductive layer in FIG. 3;

FIG. 7 is a structural layout of a second conductive layer in FIG. 3;

FIG. 8 is a structural layout of a second active layer in FIG. 3;

FIG. 9 is a structural layout of a third conductive layer in FIG. 3;

FIG. 10 is a structural layout of a fourth conductive layer in FIG. 3;

FIG. 11 is a structural layout of a fifth conductive layer in FIG. 3;

FIG. 12 is a structural layout of an electrode layer in FIG. 3;

FIG. 13 is a structural layout of the shielding layer and the first active layer in FIG. 3;

FIG. 14 is a structural layout of the shielding layer, the first active layer, and the first conductive layer in FIG. 3;

FIG. 15 is a structural layout of the shielding layer, the first active layer, the first conductive layer, and the second conductive layer in FIG. 3;

FIG. 16 is a structural layout of the shielding layer, the first active layer, the first conductive layer, the second conductive layer, and the second active layer in FIG. 3;

FIG. 17 is a structural layout of the shielding layer, the first active layer, the first conductive layer, the second conductive layer, the second active layer and the third conductive layer in FIG. 3;

FIG. 18 is a structural layout of the shielding layer, the first active layer, the first conductive layer, the second conductive layer, the second active layer, the third conductive layer and the fourth conductive layer in FIG. 3;

FIG. 19 is a structural layout of the shielding layer, the first active layer, the first conductive layer, the second conductive layer, the second active layer, the third conductive layer, the fourth conductive layer and the fifth conductive layer in FIG. 3;

FIG. 20 is a partial cross-sectional view of the display panel shown in FIG. 3 taken along a dotted line AA;

FIG. 21 is a schematic structural diagram of a fifth conductive layer of a display panel in another example embodiment of the present disclosure;

FIG. 22 is a schematic structural diagram of a fourth conductive layer of a display panel in another example embodiment of the present disclosure.

### DETAILED DESCRIPTION

Example embodiments will now be described more fully with reference to the accompanying drawings. Example embodiments may, however, be embodied in various forms and should not be construed as being limited to the examples set forth herein; rather, these embodiments are provided so that the present disclosure will be thorough and complete and will fully convey the concepts of the example embodiments to those skilled in the art. The same reference numerals in the drawings indicate the same or similar structures, and thus their detailed descriptions will be omitted.

The words “one”, “a/an”, and “the/said” are used to indicate the presence of one or more elements/components/etc.; the terms “comprising/comprises/comprise” and “having/has/have” are used to indicate an open-ended inclusion, and means that there may be additional elements/components/etc. in addition to the listed elements/components/etc.

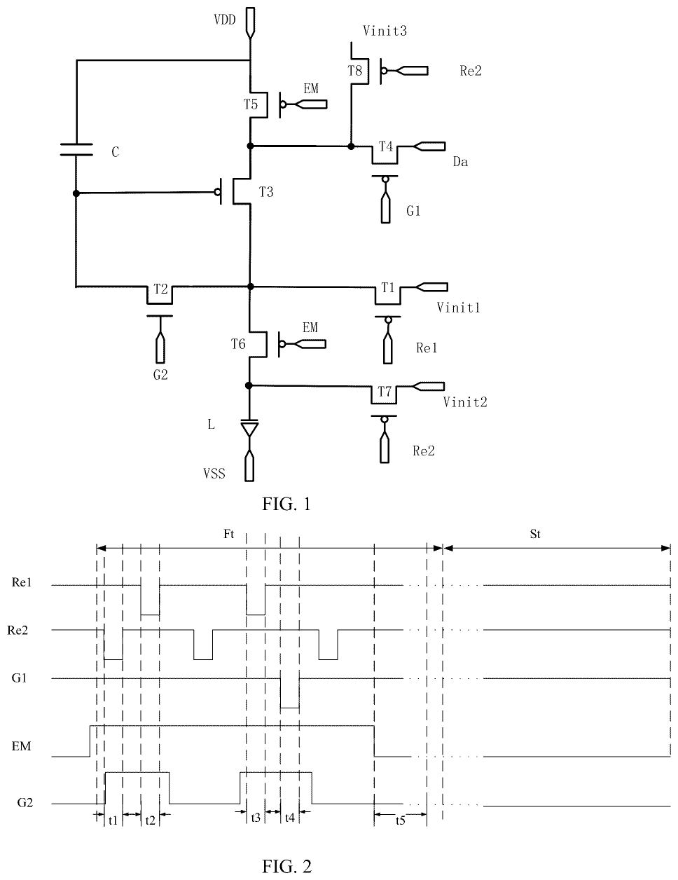

An example embodiment provides a display panel. As shown in FIG. 1, it is a schematic circuit structure diagram of a pixel driving circuit of a display panel according to an example embodiment of the present disclosure. The pixel driving circuit may include: a first transistor T1, a second transistor T2, a driving transistor T3, a fourth transistor T4, a fifth transistor T5, a sixth transistor T6, a seventh transistor T7, an eighth transistor T8, and a capacitor C. A first electrode of the second transistor T2 is connected to a gate electrode of the driving transistor T3, a second electrode of the second transistor T2 is connected to a second electrode of the driving transistor T3, and a gate electrode of the second transistor T2 is connected to a second gate driving signal terminal G2. A first electrode of the first transistor T1 is connected to a first initialization signal terminal Vinit1, a second electrode of the first transistor T1 is connected to the second electrode of the second transistor T2, and a gate electrode of the first transistor T1 is connected to a first reset signal terminal Re1. A first electrode of the fourth transistor T4 is connected to a data signal terminal Da, a second electrode of the fourth transistor T4 is connected to a first electrode of the driving transistor T3, and a gate electrode of the fourth transistor T4 is connected to a first gate driving signal terminal G1. A first electrode of the fifth transistor T5 is connected to a first power terminal VDD, a second electrode of the fifth transistor T5 is connected to the first electrode of the driving transistor T3, and a gate electrode of the fifth transistor T5 is connected to an enable signal terminal EM. A first electrode of the sixth transistor T6 is connected to the second electrode of the driving transistor T3, and a gate electrode of the sixth transistor T6 is connected to the enable signal terminal EM. A first electrode of the seventh transistor T7 is connected to a second initialization signal terminal Vinit2, a second electrode of the seventh transistor T7 is connected to a second electrode of the sixth transistor T6, and a gate electrode of the seventh transistor T7 is connected to a second reset signal terminal Re2. A first electrode of the eighth transistor T8 is connected to a third initialization signal terminal Vinit3, a second electrode of the eighth transistor T8 is connected to the first electrode of the driving transistor T3, and a gate electrode of the eighth transistor T8 is connected to the second reset signal terminal Re2. A first electrode of the capacitor is connected to the gate electrode of the driving transistor T3, and a second electrode of the capacitor is connected to the first power terminal VDD. The pixel driving circuit may be used to drive the light-emitting unit L to emit light. A first electrode of the light-emitting unit L is connected to the second electrode of the sixth transistor T6, and a second electrode of the light-emitting unit L is connected to a second power terminal VSS. The first transistor T1, the driving transistor T3, the fourth transistor T4, the fifth transistor T5, the sixth transistor T6, the seventh transistor T7, and the eighth transistor T8 may all be P-type transistors, and the second transistor T2 may be an N-type transistor.

As shown in FIG. 2, it is a timing diagram illustrating signals on respective nodes in the pixel driving circuit shown in FIG. 1. In the figure, EM represents a timing diagram of a signal on the enable signal terminal; G1 represents a timing diagram of a signal on the first gate driving signal terminal; G2 represents a timing diagram of a signal on the second gate driving signal terminal; Re1 represents a timing diagram of a signal on the first reset signal terminal; and Re2 represents a timing diagram of a signal on the second reset signal terminal.

The driving method for the pixel driving circuit in the present disclosure may include a scanning frame Ft and a holding frame St. The scanning frame Ft may include: a first reset stage t1, a second reset stage t2, a third reset stage t3, a data writing stage t4, and a light-emitting stage t5. In the first reset stage t1: the second gate driving signal terminal G2 outputs a high-level signal, the second reset signal terminal Re2 outputs a low-level signal, and the second transistor T2, the seventh transistor T7, and the eighth transistor T8 are turned on. The second initialization signal terminal Vinit2 inputs a second initialization signal to the first electrode of the light-emitting unit L, and the third initialization signal terminal Vinit3 inputs a third initialization signal to the first electrode of the driving transistor. At the same time, the driving transistor T3 may be turned on, and the third initialization signal terminal Vinit3 may write the reset signal Vinit3+Vth to the gate electrode of the driving transistor, where Vinit3 is the voltage of the third initialization signal and Vth is the threshold voltage of the driving transistor T3. In the second reset stage t2: the second gate driving signal terminal G2 outputs a high-level signal, the first reset signal terminal Re1 outputs a low-level signal, the first transistor T1 and the second transistor T2 are turned on, and the first initialization signal terminal Vinit1 inputs a first initialization signal to the gate electrode of the driving transistor T3. In the third reset stage t3: the second gate driving signal terminal G2 outputs a high-level signal, the first reset signal terminal Re1 outputs a low-level signal, the first transistor T1 and the second transistor T2 are turned on, and the first initialization signal terminal Vinit1 inputs the first initialization signal to the gate electrode of the driving transistor T3. In the data writing stage t4: the first gate driving signal terminal G1 outputs a low-level signal, the second gate driving signal terminal G2 outputs a high-level signal, the second transistor T2 and the fourth transistor T4 are turned on, and the data signal terminal Da outputs a data signal to write a compensation voltage Vdata+Vth to the gate electrode of the driving transistor, where Vdata is the voltage of the data signal and Vth is the threshold voltage of the driving transistor T3. In the light-emitting stage t5: the enable signal terminal EM outputs a low-level signal, the fifth transistor T5 and the sixth transistor T6 are turned on, and the driving transistor T3 drives the light-emitting unit L to emit light under the action of the voltage Vdata+Vth of the gate electrode of the driving transistor T3. According to the driving transistor output current formula I=(μWCox/2L)(Vgs−Vth)², where μ is the carrier mobility, Cox is the gate capacitance per unit area, W is the width of the channel of the driving transistor, L is the length of the channel of the driving transistor, Vgs is the gate-source voltage difference of the driving transistor, and Vth is the threshold voltage of the driving transistor, the output current of the driving transistor in the pixel driving circuit of the present disclosure is I=(μWCox/2L)(Vdata+Vth−Vdd−Vth)². The pixel driving circuit can avoid the influence of the driving transistor threshold on its output current.

In the example embodiment, the gate electrode of the driving transistor T3 is connected to the first initialization signal terminal through the second transistor T2 and the first transistor T1, so that the leakage current of the driving transistor T3 to the first initialization signal terminal during the light-emitting stage can be reduced. In addition, in the first reset stage t1, the third initialization signal terminal inputs a reset signal to the gate electrode of the driving transistor, and the third initialization signal is input to the first electrode of the driving transistor. This setting can restore hysteresis of the driving transistor T3 due to the previous frame bias voltage and solve the problem such as the brightness of the first frame being dark.

In an example embodiment, the timing of the first reset signal terminal, the second reset signal terminal and the enable signal terminal in the holding frame St may be the same as their timing in the scanning frame. This setting can make the driving transistor have the same hysteresis state in the scanning frame and the holding frame, to improve the flickering problem of the display panel caused by inconsistent brightness of adjacent frames.

It should be noted that in other example embodiments, the pixel driving circuit may further have other driving methods, and the present disclosure does not limit the driving method for the pixel driving circuit.

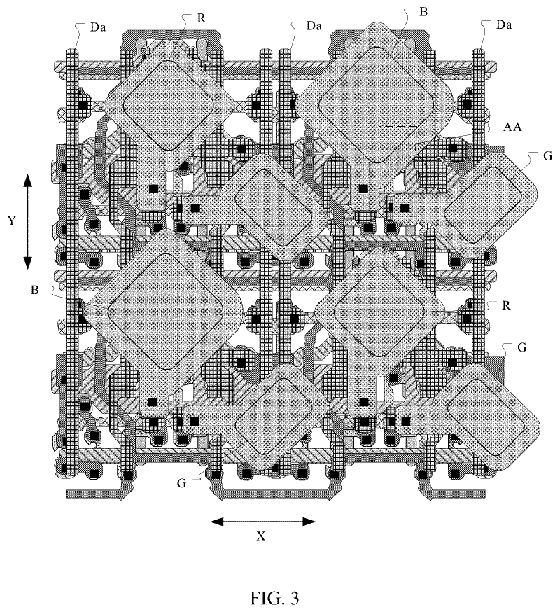

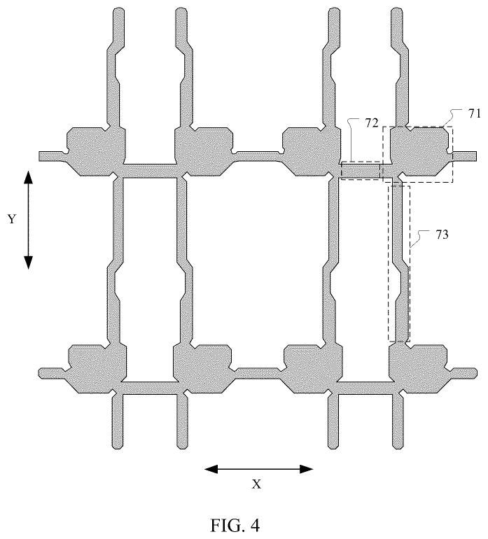

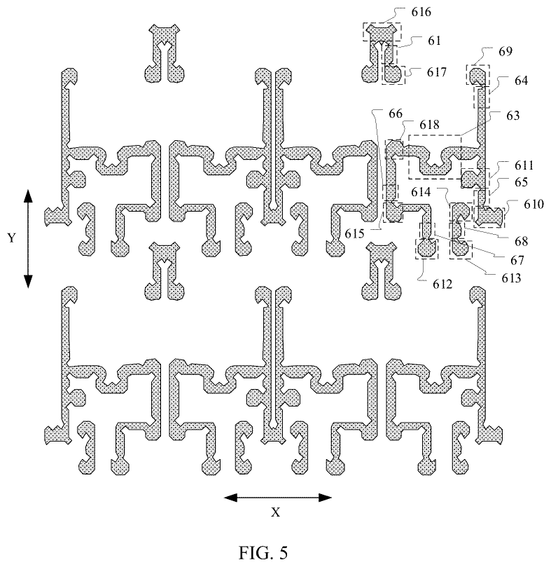

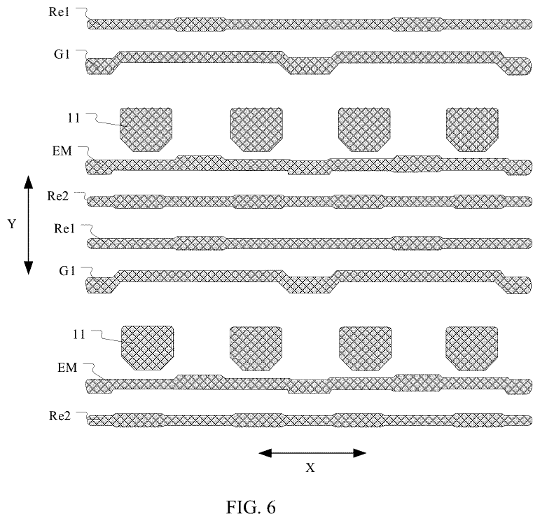

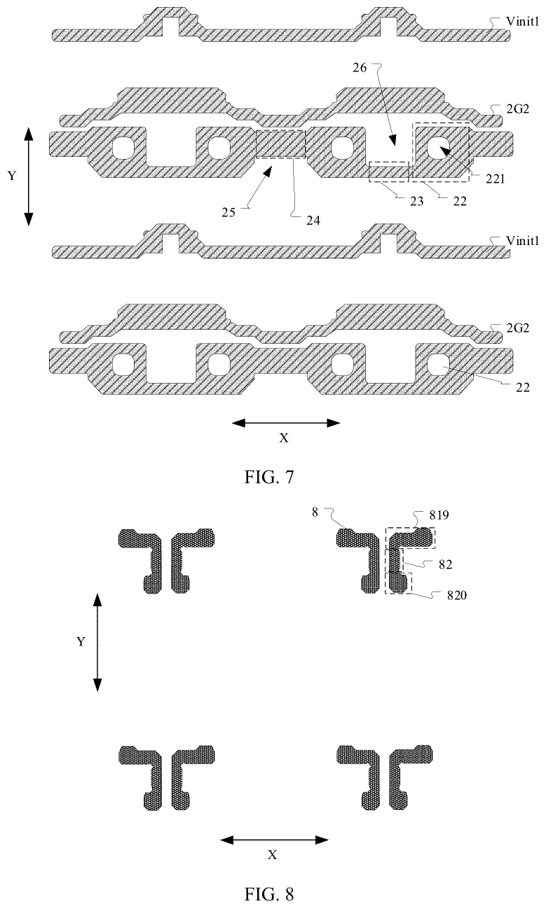

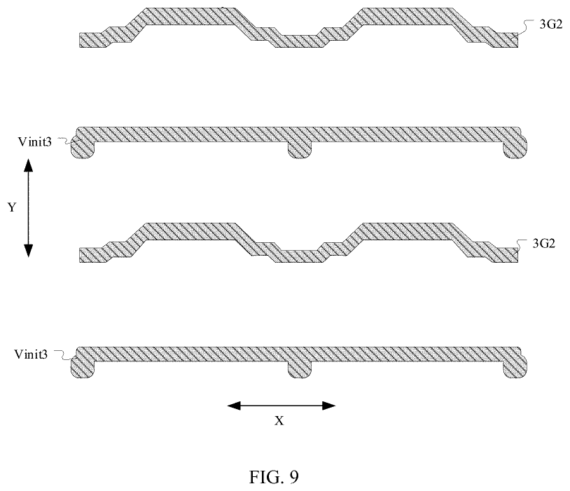

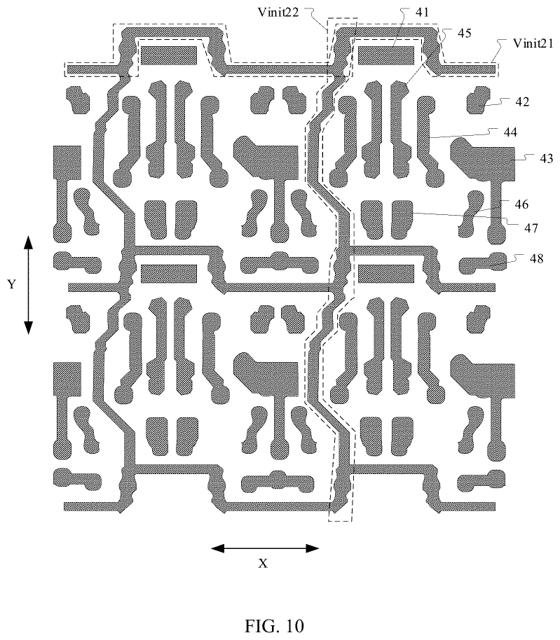

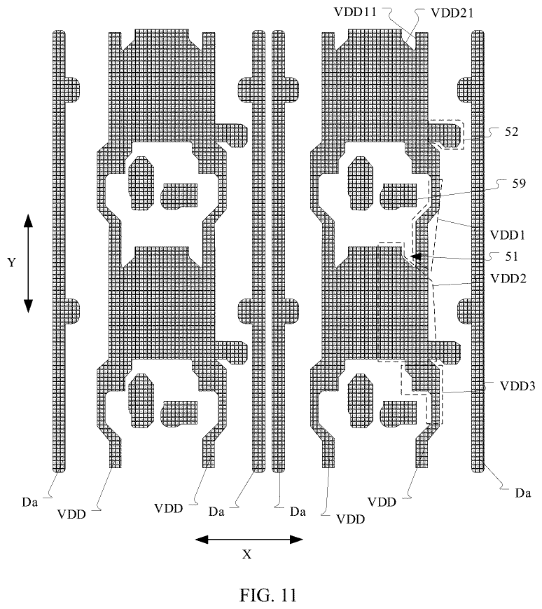

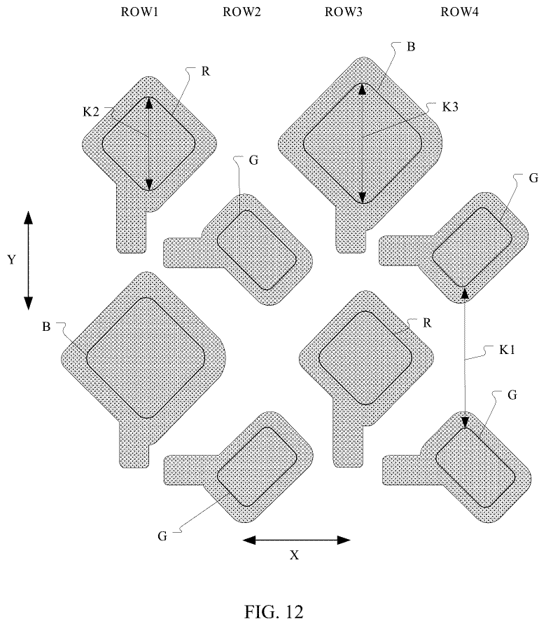

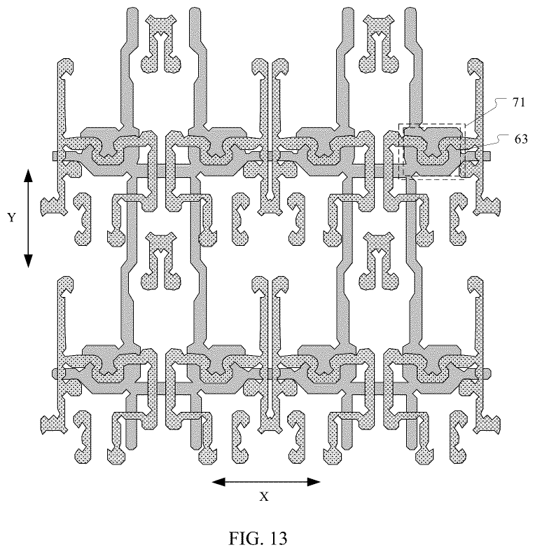

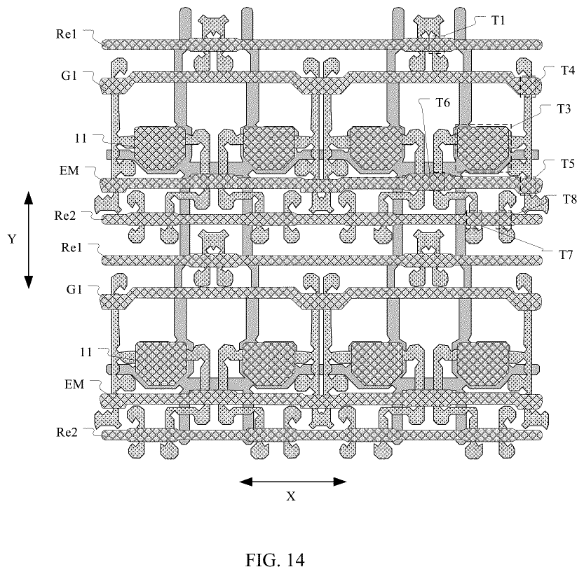

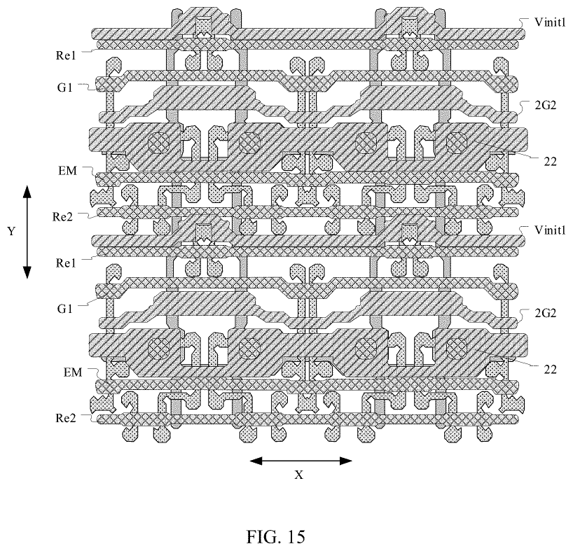

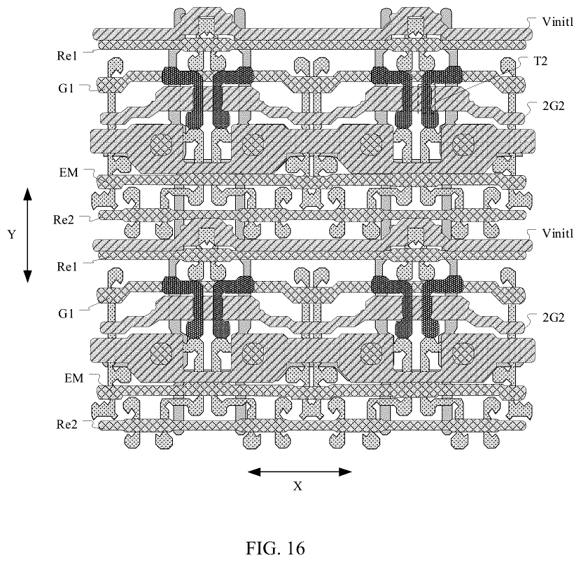

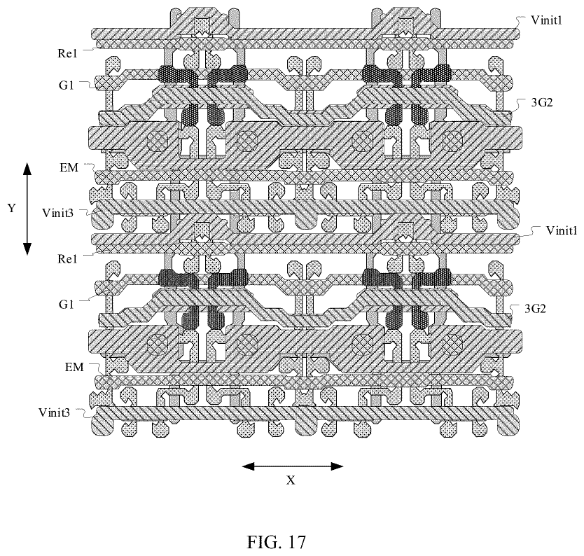

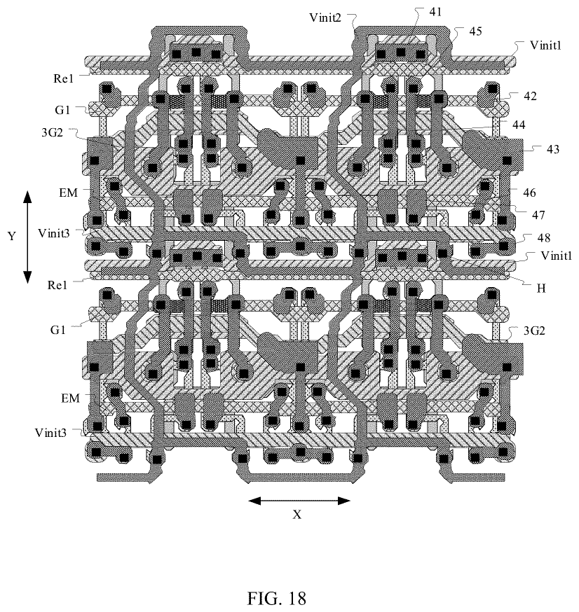

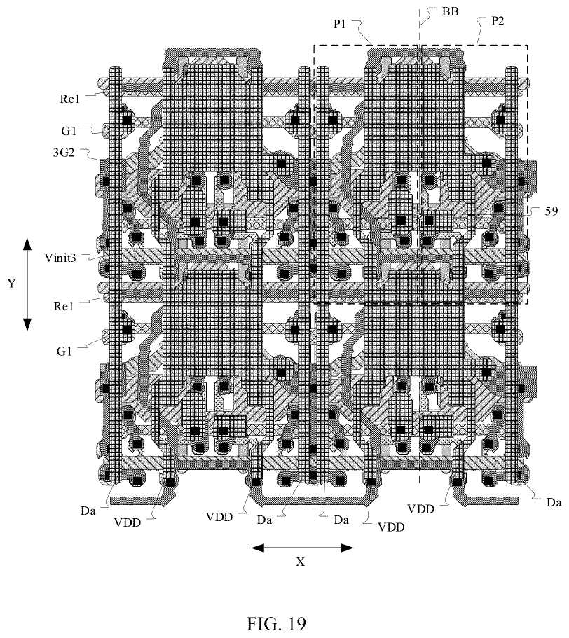

In an example embodiment, the display panel may include a base substrate, a shielding layer, a first active layer, a first conductive layer, a second conductive layer, a second active layer, a third conductive layer, a four conductive layer, a fifth conductive layer, and an electrode layer which are stacked sequentially. An insulating layer may be provided between adjacent layers among the above layers. As shown in FIGS. 3 to 19, FIG. 3 is a structural layout of a display panel in an example embodiment of the present disclosure. FIG. 4 is a structural layout of the shielding layer in FIG. 3. FIG. 5 is a structural layout of the first active layer in FIG. 3. FIG. 6 is a structural layout of the first conductive layer in FIG. 3. FIG. 7 is a structural layout of the second conductive layer in FIG. 3. FIG. 8 is a structural layout of the second active layer in FIG. 3. FIG. 9 is a structural layout of the third conductive layer in FIG. 3. FIG. 10 is a structural layout of the fourth conductive layer in FIG. 3. FIG. 11 is a structural layout of the fifth conductive layer in FIG. 3. FIG. 12 is a structural layout of the electrode layer in FIG. 3. FIG. 13 is a structural layout of the shielding layer and the first active layer in FIG. 3. FIG. 14 is a structural layout of the shielding layer, the first active layer and the first conductive layer in FIG. 3. FIG. 15 is a structural layout of the shielding layer, the first active layer, the first conductive layer and the second conductive layer in FIG. 3. FIG. 16 is a structural layout of the shielding layer, the first active layer, the first conductive layer, the second conductive layer, and the second active layer in FIG. 3. FIG. 17 is a structural layout of the shielding layer, the first active layer, the first conductive layer, the second conductive layer, the second active layer, and the third conductive layer in FIG. 3. FIG. 18 is a structural layout of the shielding layer, the first active layer, the first conductive layer, the second conductive layer, the second active layer, the third conductive layer, and the fourth conductive layer in FIG. 3. FIG. 19 is a structural layout of the shielding layer, the first active layer, the first conductive layer, the second conductive layer, the second active layer, the third conductive layer, the fourth conductive layer and the fifth conductive layer in FIG. 3. The display panel may include a plurality of pixel driving circuits shown in FIG. 1. As shown in FIG. 19, the plurality of pixel driving circuits may include a first pixel driving circuit P1 and a second pixel driving circuit P2 adjacently distributed in a first direction X. At least part of the structures of the first pixel driving circuit P1 and the second pixel driving circuit of P2 may be arranged in mirror symmetry with respect to the mirror symmetry plane BB. The mirror symmetry plane BB may be perpendicular to the base substrate. And, at least part of the structures of an orthographic projection of the first pixel driving circuit P1 on the base substrate and an orthographic projection of the second pixel driving circuit P2 on the base substrate may be arranged symmetrically with an intersection line of the mirror symmetry plane BB and the base substrate as an axis of symmetry. The first pixel driving circuit P1 and the second pixel driving circuit P2 may form a repeating unit. The display panel may include a plurality of repeating units distributed in an array in the first direction X and a second direction Y. The second direction Y may intersect the first direction X. For example, the first direction X may be a row direction, and the second direction Y may be a column direction.

As shown in FIGS. 3, 4 and 13, the shielding layer may include a plurality of shielding portions 71, connection portions 73 and connection portions 72. An orthographic projection of a connection portion 73 on the base substrate extends along the second direction Y, and is connected between shielding portions 71 which are adjacent in the second direction Y. An orthographic projection of a connection portion 72 on the base substrate extends along the first direction X, and is connected between shielding portions 71 which are adjacent in the first direction X.

As shown in FIGS. 3, 5, 13 and 14, the first active layer may include a first active portion 61, a third active portion 63, a fourth active portion 64, a fifth active portion 65, a sixth active portion 66, a seventh active portion 67, and an eighth active portion 68. The first active portion 61 is used to form a channel region of the first transistor T1. The third active portion 63 is used to form a channel region of the driving transistor T3. The fourth active portion 64 is used to form a channel region of the fourth transistor T4. The fifth active portion 65 is used to form a channel region of the fifth transistor T5. The sixth active portion 66 is used to form a channel region of the sixth transistor T6. The seventh active portion 67 is used to form a channel region of the seventh transistor T7. The eighth active portion 68 is used to form a channel region of the eighth transistor T8. In addition, the first active layer may further include: a ninth active portion 69, a tenth active portion 610, an eleventh active portion 611, a twelfth active portion 612, a thirteenth active portion 613, a fourteenth active portion 614, a fifteenth active portion 615, a sixteenth active portion 616, a seventeenth active portion 617, and an eighteenth active portion 618. The ninth active portion 69 is connected to an end of the fourth active portion 64 away from the third active portion 63. The tenth active portion 610 is connected to an end of the fifth active portion 65 away from the third active portion 63. In repeating units which are adjacent in the first direction X, adjacent fifth active portions 65 are connected through a tenth active portion 610; the eleventh active portion 611 is connected between the fifth active portion 65 and the third active portion 63; the twelfth active portion 612 is connected to an end of the seventh active portion 67 away from the sixth active portion 66; the thirteenth active portion 613 and the fourteenth active portion 614 are respectively connected to both ends of the eighth active portion 68; the fifteenth active portion 615 is connected between the sixth active portion 66 and the seventh active portion 67; the sixteenth active portion 616 and the seventeenth active portion 617 are connected to both ends of the first active portion 61. In a same repeating unit, two adjacent first active portions 61 are connected through a sixteenth active portion 616; the eighteenth active portion 618 is connected between the third active portion 63 and the sixth active portion 66. In the first direction, an orthographic projection of the eighth active portion 68 on the base substrate is located between an orthographic projection of the seventh active portion 67 on the base substrate and an orthogonal projection of the fifth active portion 65 on the base substrate.

As shown in FIGS. 3, 5, 13, and 14, an orthographic projection of a shielding portion 71 on the base substrate may cover an orthographic projection of a third active portion 63 on the base substrate, and the shielding portion 71 may block light for the third active portion 63 to reduce the impact of light on the driving characteristic of the driving transistor T3. In addition, the shielding layer may be a conductive material, and the shielding layer may also be connected to a stable voltage source to shield the driving transistor T3 from noise. For example, the shielding layer may be connected to the first power terminal VDD, the first initialization signal terminal Vinit1, the second initialization signal terminal Vinit2, the third initialization signal terminal Vinit3, the second power terminal VSS, etc. The first active layer may be formed of polysilicon material. Correspondingly, the first transistor T1, the driving transistor T3, the fourth transistor T4, the fifth transistor T5, the sixth transistor T6, the seventh transistor T7, and the eighth transistor T8 may be P-type low-temperature polysilicon thin film transistors.

As shown in FIGS. 3, 6 and 14, the first conductive layer may include a first reset signal line Re1, a first gate line G1, an enable signal line EM, a second reset signal line Re2, and a first conductive portion 11. Orthographic projections of the first reset signal line Re1, the first gate line G1, the enable signal line EM, and the second reset signal line Re2 on the base substrate may extend along the first direction X. The first reset signal line Re1 may be used to provide the first reset signal terminal in FIG. 1. The orthographic projection of the first reset signal line Re1 on the base substrate may cover the orthographic projection of the first active portion 61 on the base substrate, and a partial structure of the first reset signal line Re1 may be used to form the gate electrode of the first transistor T1. The first gate line G1 may be used to provide the first gate driving signal terminal in FIG. 1. The orthographic projection of the first gate line G1 on the base substrate may cover the orthographic projection of the fourth active portion 64 on the base substrate. A partial structure of the first gate line G1 may be used to form the gate electrode of the fourth transistor T4. The enable signal line EM is used to provide the enable signal terminal in FIG. 1. The orthographic projection of the enable signal line EM on the base substrate may cover the orthographic projection of the fifth active portion 65 on the base substrate and the orthographic projection of the sixth active portion 65 on the base substrate, a partial structure of the enable signal line EM may be used to form the gate electrode of the fifth transistor T5, and another partial structure of the enable signal line EM may be used to form the gate electrode of the sixth transistor T6. The second reset signal line Re2 is used to provide the second reset signal terminal in FIG. 1. The orthographic projection of the second reset signal line Re2 on the base substrate may cover the orthographic projection of the seventh active portion 67 on the base substrate. A partial structure of the second reset signal line Re2 may be used to form the gate electrode of the seventh transistor T7. The orthographic projection of the first conductive portion 11 on the base substrate may cover the orthographic projection of the third active portion 63 on the base substrate, and the first conductive portion 11 may be used to form the gate electrode of the driving transistor T3 and the first electrode of the capacitor C.

As shown in FIGS. 3, 6 and 14, the orthographic projection of the first reset signal line Re1 on the base substrate, the orthographic projection of the first gate line G1 on the base substrate, the orthographic projection of the first conductive portion 11 on the base substrate, the orthographic projection of the enable signal line EM on the base substrate, and the orthographic projection of the second reset signal line Re2 on the base substrate may be sequentially distributed along the second direction Y. In addition, in the display panel, the first conductive layer may be used as a mask to perform conductorization processing on the first active layer, that is, a region of the first active layer covered by the first conductive layer may form a channel region of a transistor, and a region of the first active layer not covered by the first conductive layer forms a conductor structure.

As shown in FIGS. 3, 7 and 15, the second conductive layer may include a third gate line 2G2, a first initialization signal line Vinit1, and a second conductive portion 22. Both the orthographic projection of the first initialization signal line Vinit1 on the base substrate and the orthographic projection of the third gate line 2G2 on the base substrate may extend along the first direction X. The first initialization signal line Vinit1 is used to provide the first initialization signal terminal in FIG. 1. The third gate line 2G2 is used to provide the second gate driving signal terminal in FIG. 1. The orthographic projection of the second conductive portion 22 on the base substrate may overlap with the orthographic projection of the first conductive portion 11 on the base substrate, and the second conductive portion 22 may be used to form the second electrode of the capacitor C. It should be understood that in other example embodiments, the first initialization signal line Vinit1 may also be located in other conductive layers. For example, the first initialization signal line Vinit1 may also be located in a shielding layer, a third conductive layer, a fourth conductive layer, etc., As shown in FIG. 7, the second conductive layer further includes a first connection portion 23 and a second connection portion 24. The first connection portion 23 is connected between two second conductive portions 22 in a same repeating unit, and the second connection portion 24 is connected between two adjacent second conductive portions 22 in repeating units which are adjacent in the first direction X. An opening 221 is also formed in the second conductive portion 22.

As shown in FIGS. 3, 8 and 16, the second active layer may include a plurality of active portions 8. An active portion 8 includes a second active portion 82, a nineteenth active portion 819, and a twentieth active portion 820. The second active portion 82 is connected between the nineteenth active portion 819 and the twentieth active portion 820, and the second active portion 82 is used to form the channel region of the second transistor. The orthographic projection of the third gate line 2G2 on the base substrate may cover the orthographic projection of the second active portion 82 on the base substrate, and a partial structure of the third gate line 2G2 may be used to form a bottom gate electrode of the second transistor T2. In the first direction X, the orthographic projection of the third active portion 63 on the base substrate is located between the orthographic projection of the second active portion 82 on the base substrate and the orthogonal projection of the fourth active portion 64 on the base substrate. The second active layer may be formed of indium gallium zinc oxide, and accordingly, the second transistor T2 may be an N-type metal oxide thin film transistor.

As shown in FIGS. 3, 9 and 17, the third conductive layer may include: a second gate line 3G2, and a third initialization signal line Vinit3. Both the orthographic projection of the second gate line 3G2 on the base substrate and the orthographic projection of the third initialization signal line Vinit3 on the base substrate may extend along the first direction X. The second gate line 3G2 is used to provide the second gate driving signal terminal in FIG. 1, the orthographic projection of the second gate line 3G2 on the base substrate may cover the orthographic projection of the second active portion 82 on the base substrate, and a partial structure of the second gate line 3G2 may be used to form a top gate electrode of the second transistor T2. The second gate line 3G2 and the third gate line 2G2 for the same row of pixel driving circuits may be connected through a via hole, and the via hole connected between the second gate line 3G2 and the third gate line 2G2 may be located in an edge wiring region outside the display region of the display panel. The third initialization signal line Vinit3 may be used to provide the third initialization signal terminal in FIG. 1. The orthographic projection of the third initialization signal line Vinit3 on the base substrate may overlap with the orthographic projection of the second reset signal line Re2 on the base substrate. This arrangement can improve the transmittance of the display panel. In addition, in the display panel, the third conductive layer may be used as a mask to perform conductorization processing on the second active layer, that is, a region in the second active layer covered by the third conductive layer may form a channel region of a transistor, and a region in the second active layer not covered by the third conductive layer forms a conductor structure.

As shown in FIGS. 3, 10 and 18, the fourth conductive layer may include: a second initialization signal line Vinit2, a first bridge portion 41, a second bridge portion 42, a third bridge portion 43, a fourth bridge portion 44, a fifth bridge portion 45, a sixth bridge portion 46, a seventh bridge portion 47, and an eighth bridge portion 48. The second initialization signal line Vinit2 may be used to provide the second initialization signal terminal in FIG. 1. The second initialization signal line Vinit2 may include a first initialization signal sub-line Vinit21 and a second initialization signal sub-line Vinit22. The orthographic projection of the first initialization signal sub-line Vinit21 on the base substrate extends along the first direction X, the orthographic projection of the second initialization signal sub-line Vinit22 on the base substrate extends along the second direction Y, and the orthographic projection of the first initialization signal sub-line Vinit21 on the base substrate intersects the orthographic projection of the second initialization signal sub-line Vinit22 on the base substrate. For each row of pixel driving circuits, a first initialization signal sub-line Vinit21 may be provided correspondingly. For each column of repeating units, a second initialization signal sub-line Vinit22 may be provided correspondingly. First initialization signal sub-lines Vinit21 and second initialization signal sub-lines Vinit22 may form a grid structure. This arrangement can reduce the self-resistance of the second initialization signal line, thereby reducing the voltage difference of the second initialization signal terminal at different positions of the display panel. The second initialization signal line Vinit2 may be connected to the twelfth active portion 612 through a via hole H to connect the second initialization signal terminal and the first electrode of the seventh transistor T7. In this example embodiment, black squares represent the locations of via holes. An adjacent insulating layer at a side of the fourth conductive layer facing the base substrate may have a protruding structure at the positions of the third gate line 2G2 and the second gate line 3G2, which may easily cause the second initialization signal sub-line Vinit22 to break. In this example embodiment, the third gate line 2G2 and the second gate line 3G2 each include two sides extending along the first direction X. The orthographic projection of the second initialization signal sub-line Vinit2 on the base substrate and the orthographic projections of both sides of the third gate line 2G2 on the base substrate are perpendicular or nearly perpendicular to each other. For example, the orthographic projection of the second initialization signal sub-line Vinit2 on the base substrate and the orthographic projections of the two sides of the third gate line 2G2 on the base substrate form angles greater than or equal to 80° and less than or equal to 100°. The angles formed by the orthographic projection of the second initialization signal sub-line Vinit2 on the base substrate and the orthogonal projections of two sides of the third gate line 2G2 on the base substrate may be equal to 80°, 90°, 100°, etc. The orthographic projection of the second initialization signal sub-line Vinit2 on the base substrate is perpendicular or nearly perpendicular to the orthographic projections of two sides of the second gate line 3G2 on the base substrate. For example, the orthographic projection of the second initialization signal sub-line Vinit2 on the base substrate and the orthographic projections of two sides of the second gate line 3G2 on the base substrate form angles greater than or equal to 80° and less than or equal to 100°. The angles formed by the orthographic projection of the second initialization signal sub-line Vinit2 on the base substrate and the orthographic projections of two sides of the second gate line 3G2 on the base substrate may be equal to 80°, 90°, 100°, etc. This arrangement can reduce the risk of breakage of the second initialization signal sub-line Vinit2. In addition, in this example embodiment, for a part of the sides of the third gate line 2G2 whose orthographic projection on the base substrate intersects the orthographic projection of the second initialization signal sub-line Vinit22 on the base substrate and a part of the sides of the third gate line 2G2 whose orthographic projection on the base substrate intersects the orthographic projection of the second initialization signal sub-line Vinit22 on the base substrate, their orthographic projections do not overlap. This arrangement allows the adjacent insulating layer at the side of the fourth conductive layer facing the base substrate to form a slop at the positions of the third gate line 2G2 and the second gate line 3G2, and thus this arrangement can also reduce the risk of breakage of the second initialization signal sub-line Vinit2. The first bridge portion 41 may be connected to the sixteenth active portion 616 and the first initialization signal line Vinit1 through via holes respectively, so as to connect the first electrode of the first transistor T1 and the first initialization signal terminal. The second bridge portion 42 may be connected to the ninth active portion 69 through a via hole to connect to the first electrode of the fourth transistor T4. The third bridge portion 43 may be connected to a second connection portion 24 and the tenth active portion 610 through via holes respectively to connect the first electrode of the fifth transistor T5 and the second electrode of the capacitor. The fourth bridge portion 44 may be connected to the nineteenth active portion 819 and the first conductive portion 11 through via holes respectively to connect the first electrode of the second transistor T2 and the gate electrode of the driving transistor T3. The orthographic projection of a via hole connected between the first conductive portion 11 and the fourth bridge portion 44 on the base substrate is located within the orthographic projection of the opening 221 on the base substrate, so that the via hole connected between the first conductive portion 11 and the fourth bridge portion 44 is insulated from the second conductive portion 22. The orthographic projection of the fourth bridge portion 44 on the base substrate may extend along the second direction Y and intersects the orthographic projection of the second gate line 3G2 on the base substrate. The fifth bridge portion 45 may be connected to the seventeenth active portion 617, the eighteenth active portion 618 and the twentieth active portion 820 through via holes respectively to connect the second electrode of the first transistor T1 and the second electrode of the driving transistor T3 and second electrode of the second transistor T2. The orthographic projection of the fifth bridge portion 45 on the base substrate may at least partially overlap with the orthographic projection of an active portion 8 on the base substrate, and this arrangement can improve the transmittance of the display panel. In addition, the orthographic projection of the fifth bridge portion 45 on the base substrate may extend along the second direction Y and intersects the orthographic projection of the second gate line 3G2 on the base substrate. The sixth bridge portion 46 may be connected to the eleventh active portion 611 and the fourteenth active portion 614 through via holes respectively to connect the second electrode of the eighth transistor and the first electrode of the driving transistor T3. The seventh bridge portion 47 may be connected to the fifteenth active portion 615 through a via hole to connect the second electrode of the sixth transistor. The eighth bridge portion 48 may be connected to the thirteenth active portion 613 and the third initialization signal line Vinit3 through via holes respectively, so as to connect the first electrode of the eight transistor T8 and the third initialization signal terminal. It should be understood that in other example embodiments, the second initialization signal line Vinit2 may also be located in other conductive layers. For example, the second initialization signal line Vinit2 may be located in a shielding layer, a second conductive layer, a third conductive layer, etc.; The second initialization signal line Vinit2 may alternatively include only the first initialization signal sub-line Vinit21 or the second initialization signal sub-line Vinit22.

In an example embodiment, a plurality of second gate lines 3G2 for a plurality of rows of pixel driving circuit may be provided with the second gate driving signal by a same signal terminal. For example, two second gate lines 3G2 for adjacent rows of odd-numbered and even-numbered pixel driving circuits may be provided with the second gate driving signal by a same stage of shift register unit in the gate driving circuit. In an example embodiment, an equipotential structure of the first electrode of the driving transistor T3 forms a parasitic capacitance with other conductive structure. After the fourth transistor T4 is turned off, the equipotential structure of the first electrode of the driving transistor T3 may continue to write a compensation voltage to the gate electrode of the driving transistor. For two rows of pixel driving circuits that receive the same second gate driving signal, both rows of pixel driving circuits need to turn on the second transistor T2 during a data writing stage. Therefore, the time duration for the pixel driving circuit of the previous row to write the compensation voltage to the gate electrode of the driving transistor through the equipotential structure of the first electrode of the driving transistor T3 is longer than the time duration for the pixel driving circuit of an adjacent next row to write the compensation voltage to the gate electrode of the driving transistor through the equipotential structure of the first electrode of the driving transistor T3, and this results in display differences in adjacent sub-pixel rows of the display panel.

As shown in FIG. 7, the size of the orthographic projection of a second connection portion 24 on the base substrate in the second direction Y is smaller than the size of the orthogonal projection of a second conductive portion 22 on the base substrate in the second direction Y. A second notch 25 is formed between the second connection portion 24 and the second conductive portion 22. The orthographic projection of the second notch 25 on the base substrate overlaps with the orthographic projection of the equipotential structure of the first electrode of the driving transistor T3 on the base substrate. For example, the orthographic projection of the second notch 25 on the base substrate overlaps with the orthographic projection of the sixth bridge portion 46 on the base substrate, and the orthographic projection of the eleventh active portion 611 on the base substrate. This arrangement can reduce the parasitic capacitance between the equipotential structure of the first electrode of the driving transistor T3 and other structures, thereby addressing the problem of display differences in adjacent sub-pixel rows of the display panel.

As shown in FIG. 7, the size of the orthographic projection of a first connection portion 23 on the base substrate in the second direction Y is smaller than the size of the orthogonal projection of a second conductive portion 22 on the base substrate in the second direction Y. A third notch 26 is formed between the first connection portion 23 and the second conductive portion 22. The orthographic projection of the third notch 26 on the base substrate overlaps with the orthographic projection of the equipotential structure of the second electrode of the driving transistor T3 on the base substrate. For example, the orthographic projection of the third notch 26 on the base substrate overlaps with the orthographic projection of the fifth bridge portion 45 on the base substrate. This arrangement can reduce the parasitic capacitance between the equipotential structure of the second electrode of the driving transistor T3 and other structures, thereby improving the efficiency for writing the compensation voltage to the gate electrode of the driving transistor T3 by the data signal terminal.

As shown in FIGS. 3, 8, 17 and 18, in an example embodiment, the orthographic projection of the nineteenth active portion 819 on the base substrate at least partially overlaps with the orthographic projection of the first gate line G1 on the base substrate. At the end of the data writing stage, the first gate line G1 can pull up the voltage of the gate electrode of the driving transistor T3 through the nineteenth active portion 819. This arrangement can reduce the voltage of the data signal under a black screen of the display panel, thereby reducing the power consumption of the display panel. The maximum size of the orthographic projection of the nineteenth active portion 819 on the base substrate in the first direction X may be larger than the maximum size of the orthographic projection of the nineteenth active portion 819 on the base substrate in the second direction Y. The maximum sizes of the orthographic projection of the nineteenth active portion 819 on the base substrate in the first direction X is L1, the maximum size of the orthogonal projection of the nineteenth active portion 819 on the base substrate in the second direction Y is L2, and L1/L2 may be greater than or equal to 1.5 and less than or equal to 5. For example, L1/L2 may be equal to 1.5, 2, 2.5, 3, 4, 5, etc. It is not proper for the capacitance between the nineteenth active portion 819 and the first gate line G1 to be too large, that is, in this example embodiment, it is not proper for maximum size of the orthographic projection of the nineteenth active portion 819 on the base substrate in the first direction X to be too large. If the capacitance between the nineteenth active portion 819 and the first gate line G1 is too large, the capacitance between the nineteenth active portion 819 and the first gate line G1 is susceptible to large changes caused by process errors. This leads to the problem of uneven display effects of the display panel.

In an example embodiment, the equipotential structure of the gate electrode of the driving transistor T3 and the equipotential structure of the second gate line 3G2 may also form a parasitic capacitance. For example, the fourth bridge portion 44 and the second gate line 3G2 may form a parasitic capacitance. At the end of the data writing stage, the second gate line 3G2 may pull down the voltage of the gate electrode of the driving transistor T3 through the fourth bridge portion 44. In this example embodiment, the parasitic capacitance formed by the equipotential structure of the gate electrode of the driving transistor T3 and the equipotential structure of the second gate line 3G2 may be smaller than the parasitic capacitance formed by the equipotential structure of the gate electrode of the driving transistor T3 and the equipotential structure of the first gate line G1. The capacitance formed by the equipotential structure of the first conductive portion 11 and the equipotential structure of the first gate line G1 is C1, and the capacitance formed by the equipotential structure of the first conductive portion 11 and the equipotential structure of the second gate line 3G2 is C2, and C1 is greater than C2.

The overlapping area of the orthographic projection of the nineteenth active portion 819 on the base substrate and the orthographic projection of the first gate line G1 on the base substrate is S1, and the overlapping area of the orthographic projection of the fourth bridge portion 44 on the base substrate and orthographic projection of the second gate line 3G2 on the base substrate is S2; S1/S2 may be greater than or equal to 1.2 and less than or equal to 2. For example, S1/S2 may be equal to 1.2, 1.5, 2, etc.

As shown in FIGS. 3, 11 and 19, the fifth conductive layer may include a data line Da, a power line VDD and a ninth bridge portion 59. The data line Da may be used to provide the data signal terminal in FIG. 1. The power line VDD may be used to provide the first power terminal in FIG. 1. The orthographic projection of the data line Da on the base substrate and the orthographic projection of the power line VDD on the base substrate may extend along the second direction Y. The data line Da may be connected to the second bridge portion 42 through a via hole to connect the first electrode of the fourth transistor T4 and the data signal terminal. For each column of pixel driving circuits, a power line VDD may be provided correspondingly. The power line VDD may be connected to the third bridge portion 43 through a via hole through the connection portion 52 to connect the first power terminal and the second electrode of the capacitor C and the first electrode of the fifth transistor T5. In an example embodiment, the power line VDD may include a first power line segment VDD1, a second power line segment VDD2 and a third power line segment VDD3. The second power line segment VDD2 is connected between the first power line segment VDD1 and the third power line segment VDD3. The size of the orthographic projection of the second power line segment VDD2 on the base substrate in the first direction X may be larger than the size of the orthogonal projection of the first power line segment VDD1 on the base substrate in the first direction X, and the size of the orthographic projection of the second power line segment VDD2 on the base substrate in the first direction X may be larger than the size of the orthogonal projection of the third power line segment VDD3 on the base substrate in the first direction X. In addition, the orthographic projection of the second power line segment VDD2 on the base substrate may also cover the orthographic projection of an active portion 8 on the base substrate, and the second power line segment VDD2 can reduce the impact of light on the characteristic of the second transistor T2. In addition, the orthographic projection of the power line VDD on the base substrate may also cover the orthographic projection of the fourth bridge portion 44 on the base substrate, and the power line VDD can be used to shield the noise interference of other signals on the fourth bridge portion 44, thereby improving the stability of the gate voltage of driving transistor T3. The ninth bridge portion 59 may be connected to the seventh bridge portion 47 through a via hole to connect the second electrode of the sixth transistor T6.

In other example embodiments, the first power line segment VDD1 may be widened along the first direction X, so that the orthographic projection of the first power line segment VDD1 on the base substrate overlaps with the orthographic projection of the sixth bridge portion 46 on the base substrate. On the one hand, this arrangement can reduce the resistance of the power line. On the other hand, this arrangement can regulate the voltage of the sixth bridge portion 46 through the first power line segment VDD1 to improve the stability of the voltage of the first electrode of the driving transistor. On the other hand, this arrangement can increase the parasitic capacitance of the first electrode of the driving transistor, so that after the fourth transistor T4 is turned off, the data signal stored by the parasitic capacitance can still write a compensation voltage to the gate electrode of the driving transistor.

As shown in FIGS. 3, 11 and 19, in an example embodiment, in the same repeating unit, two adjacent second power line segments VDD2 may be connected to each other. The power line VDD and the second conductive portions 22 connected in the first direction X may form a grid structure. The power line having such grid structure can have relatively small resistance, and thus reduce the voltage difference between first power terminals at different positions of the display panel, and accordingly improve the display uniformity of the display panel. It should be understood that in other example embodiments, the second conductive layer may be provided with only one of the first connection portion 23 4876-8825-2882, v. 1 and the second connection portion 24, or the second conductive layer may not be provided with the first connection portion 23 and the second connection portion 24. This arrangement can improve the transmittance of the display panel.

As shown in FIGS. 3, 11 and 19, a first notch 51 is formed in the power line VDD, and at least part of the first notch may be located in a light-transmitting region of the display panel. The light-transmitting region of the display panel may refer to a region where no light-shielding structure (such as a barrier layer, a first active layer, a first conductive layer, a second conductive layer, a second active layer, a third conductive layer, a fourth conductive layer, or a fifth conductive layer) is provided except an electrode layer. The first notch 51 may include a first side VDD21 and a second side VDD11. The first side VDD21 may be formed by a part of an edge of the second power line segment VDD2, and the second side VDD11 may be formed by a part of an edge of the first power line segment VDD1. An angle formed by the orthographic projection of the first side VDD21 on the base substrate and the orthographic projection of the second side VDD11 on the base substrate may be less than 90°. The orthographic projection of the first notch 51 on the base substrate may also overlap with the orthographic projection of a signal line such as the first initialization signal line Vinit1, or the first reset signal line Re1 on the base substrate. The first notch 51 can reduce the parasitic capacitance of a signal line such as the first initialization signal line Vinit or the first reset signal line Re1, thereby improving the charging efficiency of the signal line(s).

It should be understood that in other example embodiments, the first notch, the second notch and the third notch may also be located at other positions, and the orthographic projections of the first notch, the second notch and the third notch on the base substrate may be in other shapes, and the first notch, the second notch, and the third notch may be a closed shape or a non-closed shape.

As shown in FIGS. 3, 11 and 19, except the third bridge portion 43, the connection portion 52 and the ninth bridge portion 59, other structures of the first pixel driving circuit P1 and the second pixel driving circuit P2 may be arranged in a mirror symmetry along the mirror symmetry plane BB.

As shown in FIGS. 3 and 12, in an example embodiment, the electrode layer may include a plurality of electrode portions: a first electrode portion R, a second electrode portion B, and a third electrode portion G. Each electrode portion may be connected to a ninth bridge portion 59 through a via hole to connect to the second electrode of the sixth transistor T6. The first electrode portion R may be used to form a first electrode of a red light-emitting unit, the second electrode portion B may be used to form a first electrode of a blue light-emitting unit, and the third electrode portion G may be used to form a first electrode of a green light-emitting unit. The plurality of electrode portions are distributed in an array along the first direction X and the second direction Y. The plurality of electrode portions distributed along the first direction X form an electrode row, and the plurality of electrode portions distributed along the second direction Y form an electrode column. In the same electrode row, a first electrode portion R, a third electrode portion G, a second electrode portion B, and a third electrode portion G are distributed sequentially and alternately in the first direction X. The plurality of electrode columns include a first electrode column ROW1, a second electrode column ROW2, a third electrode column ROW3, and a fourth electrode column ROW4 which are sequentially adjacent. The first electrode column ROW1 includes a first electrode portion R and a second electrode portion B which are distributed sequentially and alternately in the second direction Y. The second electrode column ROW2 includes a plurality of third electrode portion G which are distributed in the second direction Y. The third electrode column ROW3 includes a second electrode portion B and a first electrode portion R which are distributed sequentially and alternately in the second direction Y. The fourth electrode column RWO4 includes a plurality of third electrode portion G which are distributed in the second direction Y. The minimum distance K1 in the second direction Y between orthographic projections of two third electrode portions G located in adjacent electrode rows and located in the same electrode column on the base substrate may be greater than the size K2 of the orthographic projection of the first electrode portion R on the base substrate in the second direction Y, or may be greater than the size K3 of the orthographic projection of the second electrode portion B on the base substrate in the second direction Y. The display panel may further include a pixel definition layer located at a side of the electrode layer away from the base substrate, and pixel openings for forming light-emitting units are formed in the pixel definition layer. The orthographic projection of a first electrode portion R on the base substrate coincides with the orthographic projection of its corresponding pixel opening in the pixel definition layer on the base substrate. The orthographic projection of a second electrode portion B on the base substrate coincides with the orthographic projection of its corresponding pixel opening in the pixel definition layer on the base substrate. The orthographic projection of a third electrode portion G on the base substrate coincides with the orthographic projection of its corresponding pixel opening in the pixel definition layer on the base substrate.

It should be noted that, as shown in FIGS. 3, 18 and 19, the black squares drawn at a side of the fourth conductive layer away from the base substrate represent via holes for the fourth conductive layer to connect to other layers at the side facing the base substrate; the black square drawn at a side of the fifth conductive layer away from the base substrate represent via holes for the fifth conductive layer to connect to other layers at the side facing the base substrate; the black square drawn at a side of the electrode layer away from the base substrate represent via holes for the electrode layer to connect to other layers at the side facing the base substrate. The black squares represent the locations of via holes. Different via holes represented by black squares at different positions can penetrate different insulating layers.

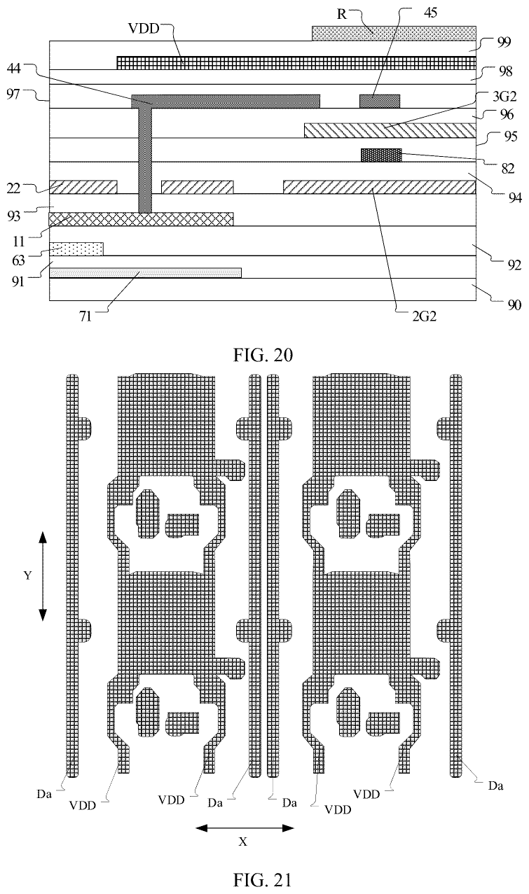

As shown in FIG. 20, it is a partial cross-sectional view of the display panel shown in FIG. 3 taken along the dotted line AA. The display panel may further include a first insulating layer 91, a second insulating layer 92, a third insulating layer 93, a fourth insulating layer 94, a fifth insulating layer 95, a first dielectric layer 96, a passivation layer 97, a first planarization layer 98, and a second planarization layer 99. The base substrate 90, the shielding layer, the first insulating layer 91, the first active layer, the second insulating layer 92, the first conductive layer, the third insulating layer 93, the second conductive layer, the fourth insulating layer 94, the second active layer, the fifth insulating layer 95, the third conductive layer, the first dielectric layer 96, the fourth conductive layer, the passivation layer 97, the first planarization layer 98, the fifth conductive layer, the second planarization layer 99 and the electrode layer are stacked in sequence. The first insulating layer 91, the second insulating layer 92, the third insulating layer 93, the fourth insulating layer 94 and the fifth insulating layer 95 may be a single-layer structure or a multi-layer structure, and the materials of the first insulating layer 91, the second insulating layer 92, the third insulating layer 93, the fourth insulating layer 94, and the fifth insulating layer 95 may be at least one of: silicon nitride, silicon oxide, and silicon oxynitride. The first dielectric layer 96 may be a silicon nitride layer. The material of the first planarization layer 98 and the second planarization layer 99 may be an organic material, such as polyimide (PI), polyethylene terephthalate (PET), polyethylene naphthalate (PEN), silicon-glass bonding structure (SOG) or other materials. The base substrate 90 may include a glass substrate, a barrier layer, and a polyimide layer that are stacked in sequence. The barrier layer may be an inorganic material. The passivation layer 97 may be a silicon oxide layer. The material of the first conductive layer, the second conductive layer, and the third conductive layer may be one of molybdenum, aluminum, copper, titanium, niobium or an alloy, or a molybdenum/titanium alloy or stacked layers of molybdenum/titanium. The material of the fourth conductive layer and the fifth conductive layer may include a metal material, for example, it may be one of molybdenum, aluminum, copper, titanium, niobium or an alloy, or a molybdenum/titanium alloy or stacked layers of molybdenum/titanium, or it may be stacked layers of titanium/aluminum/titanium. The electrode layer may include an indium tin oxide layer or a silver layer. The sheet resistance of any of the first conductive layer, the second conductive layer, and the third conductive layer may be greater than the sheet resistance of any of the fourth conductive layer and the fifth conductive layer.

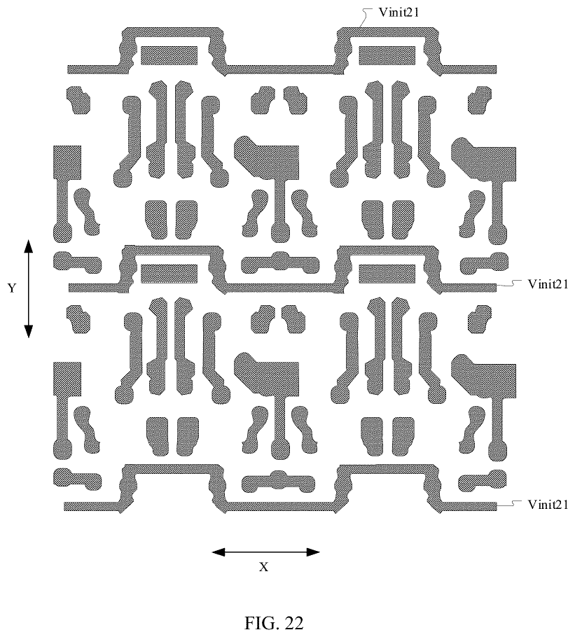

It should be understood that in other example embodiments, as shown in FIG. 21, it is a schematic structural diagram of the fifth conductive layer of the display panel in another example embodiment of the present disclosure, the first notch does not need to be provided in the power line VDD. This arrangement can reduce the resistance of the power line. As shown in FIG. 22, it is a schematic structural diagram of the fourth conductive layer of the display panel in another example embodiment of the present disclosure, the second initialization signal line may include only the first initialization signal sub-line Vinit21.

It should be noted that the scale of the drawings in the present disclosure may be used as a reference in actual processes, but the present disclosure is not limited thereto. For example, the width-to-length ratio of a channel, the thickness and spacing of respective film layers, or the width and spacing of respective signal lines can be adjusted according to actual needs. The number of pixels in the display substrate and the number of sub-pixels in each pixel are not limited to the numbers shown in the figures. The figures described in the present disclosure are only structural schematic diagrams. In addition, the qualifiers such as “first”, and “second” are only used to define different structure names and are not intended to imply specific order or quantity. In example embodiments, the orthographic projection of a certain structure on the base substrate extends along a certain direction, which can be understood as the orthographic projection of the structure on the base substrate extending straightly or in a bent manner along the direction. A transistor is a component that includes at least three terminals: a gate electrode, a drain electrode, and a source electrode. A transistor has a channel region between a drain (drain electrode terminal, drain region, or drain electrode) and a source (source electrode terminal, source region, or source electrode), and current can flow through the drain, the channel region, and the source. In an example embodiment, the channel region refers to a region through which current mainly flows. In an example embodiment, a first electrode may be a drain electrode and a second electrode may be a source electrode, or the first electrode may be a source electrode and the second electrode may be a drain electrode. When transistors with opposite polarities are used or when the direction of current changes during circuit operation, the functions of “source” and “drain” may be interchanged. Therefore, in example embodiments, “source” and “drain” may be interchanged with each other. In addition, the gate (or gate electrode) may also be called a control electrode.

An example embodiment further provides a display device, which includes the above-mentioned display panel. The display device may be a display device such as a mobile phone, a tablet computer, or a television.

Other embodiments of the present disclosure will be readily apparent to those skilled in the art from consideration of the specification and practice of the content disclosed herein. The present disclosure is intended to cover any variations, uses, or adaptations of the present disclosure that follow the general principles of the present disclosure and include common knowledge or customary technical means in the technical field that are not disclosed herein. It is intended that the specification and examples be considered as exemplary only, with a true scope and spirit of the present disclosure being indicated by the appended claims. The drawings in the present disclosure only show the structures involved in the present disclosure, and for other structures, reference may be made to common designs. If there is no conflict, the embodiments of the present disclosure and the features in the embodiments may be combined with each other to obtain new embodiments. Those of ordinary skill in the art should understand that the technical solutions of the present disclosure can be modified or equivalently substituted without departing from the spirit and scope of the technical solutions of the present disclosure, and all such modification or equivalent substitution should be covered by the scope of the claims of the present disclosure.

It is to be understood that the present disclosure is not limited to the precise structures described above and illustrated in the accompanying drawings, and various modifications and changes may be made without departing from the scope of the present disclosure. The scope of the present disclosure is limited only by the appended claims.

1. A display panel, comprising:
a pixel driving circuit, wherein the pixel driving circuit comprises a driving transistor, a first transistor and a second transistor, a first electrode of the second transistor is connected to a gate electrode of the driving transistor, a second electrode of the second transistor is connected to a second electrode of the driving transistor, a first electrode of the first transistor is connected to a first initialization signal line, and a second electrode of the first transistor is connected to the second electrode of the second transistor;
wherein the display panel further comprises:
a base substrate;
a first reset signal line, wherein an orthographic projection of the first reset signal line on the base substrate extends along a first direction, and a partial structure of the first reset signal line is used to form a gate electrode of the first transistor;
a second gate line, wherein an orthographic projection of the second gate line on the base substrate extends along the first direction, and a partial structure of the second gate line is used to form a gate electrode of the second transistor;
a first conductive portion, wherein the first conductive portion is used to form the gate electrode of the driving transistor;
wherein the orthographic projection of the second gate line on the base substrate is located between the orthographic projection of the first reset signal line on the base substrate and an orthographic projection of the first conductive portion on the base substrate.

2. The display panel according to claim 1, further comprising:
a first active portion, wherein the orthographic projection of the first reset signal line on the base substrate covers an orthographic projection of the first active portion on the base substrate, and the first active portion is used to form a channel region of the first transistor;
a second active portion, wherein the orthographic projection of the second gate line on the base substrate covers an orthographic projection of the second active portion on the base substrate, and the second active portion is used to form a channel region of the second transistor;
a seventeenth active portion connected to the first active portion;
a twentieth active portion connected to the second active portion;
a fifth bridge portion, wherein an orthographic projection of the fifth bridge portion on the base substrate extends along a second direction, the second direction intersects the first direction, and the fifth bridge portion is connected to the seventeenth active portion and the twentieth active portion through via holes respectively, and the orthographic projection of the fifth bridge portion on the base substrate intersects the orthographic projection of the second gate line on the base substrate.

3. The display panel according to claim 1, further comprising:
a first active portion, wherein the orthographic projection of the first reset signal line on the base substrate covers an orthographic projection of the first active portion on the base substrate, and the first active portion is used to form a channel region of the first transistor;
a seventeenth active portion connected to the first active portion;
a third active portion, wherein the orthographic projection of the first conductive portion on the base substrate covers an orthographic projection of the third active portion on the base substrate, and the third active portion is used to form a channel region of the driving transistor;
an eighteenth active portion connected to the third active portion;
a fifth bridge portion, wherein an orthographic projection of the fifth bridge portion on the base substrate extends along a second direction, the second direction intersects the first direction, the fifth bridge portion is connected to the seventeenth active portion and the eighteenth active portion through via holes, respectively, and the orthogonal projection of the fifth bridge portion on the base substrate intersects the orthogonal projection of the second gate line on the base substrate.

4. The display panel according to claim 2, further comprising:
a nineteenth active portion connected to a side of the second active portion away from the twentieth active portion;
a fourth bridge portion connected to the nineteenth active portion and the first conductive portion through via holes, respectively;
wherein an orthographic projection of the fourth bridge portion on the base substrate extends along the second direction and intersects the orthographic projection of the second gate line on the base substrate.

5. The display panel according to claim 1, further comprises:
a first active layer located at a side of the base substrate, wherein the first active layer comprises a first active portion, a third active portion, a seventeenth active portion and an eighteenth active portion, the first active portion is used to form a channel region of the first transistor, the third active portion is used to form a channel region of the driving transistor, the seventeenth active portion is connected to the first active portion, and the eighteenth active portion is connected to the third active portion;
a first conductive layer located at a side of the first active layer away from the base substrate, wherein the first conductive layer comprises the first reset signal line and the first conductive portion;
a second active layer located at a side of the first conductive layer away from the base substrate, wherein the second active layer comprises a second active portion, a nineteenth active portion and a twentieth active portion, the second active portion is used to form a channel region of the second transistor, and the nineteenth active portion and the twentieth active portion are respectively connected to both ends of the second active portion;
a third conductive layer located at a side of the second active layer away from the base substrate, wherein the third conductive layer comprises the second gate line;
a fourth conductive layer located at a side of the third conductive layer away from the base substrate, wherein the fourth conductive layer comprises a fourth bridge portion and a fifth bridge portion, the fourth bridge portion is connected to the nineteenth active portion and the first conductive portion through via holes, respectively, and the fifth bridge portion is connected to the eighteenth active portion, the seventeenth active portion and the twentieth active portion through via holes, respectively.

6. The display panel according to claim 1, wherein the pixel driving circuit further comprises a fourth transistor, a first electrode of the fourth transistor is connected to a data line, and a second electrode of the fourth transistor is connected to a first electrode of the driving transistor;
wherein the display panel further comprises:
a first active layer located at a side of the base substrate, wherein the first active layer comprises a third active portion and a fourth active portion, the third active portion is used to form a channel region of the driving transistor, and the fourth active portion is used to form a channel region of the fourth transistor;
a second active layer located at a side of the first active layer away from the base substrate, wherein the second active layer comprises a second active portion, the orthographic projection of the second gate line on the base substrate covers an orthographic projection of the second active portion on the base substrate, and the second active portion is used to form a channel region of the second transistor;
wherein in the first direction, an orthographic projection of the third active portion on the base substrate is located between the orthographic projection of the second active portion on the base substrate and an orthographic projection of the fourth active portion on the base substrate.

7. The display panel according to claim 4, wherein the pixel driving circuit further comprises a fourth transistor, a first electrode of the fourth transistor is connected to a data line, and a second electrode of the fourth transistor is connected to a first electrode of the driving transistor;
wherein the display panel further comprises:
a first conductive layer located at a side of the base substrate, wherein the first conductive layer comprises a first gate line, an orthographic projection of the first gate line on the base substrate extends along the first direction, and the orthographic projection of the first gate line on the base substrate is located between the orthographic projection of the first reset signal line on the base substrate and the orthographic projection of the second gate line on the base substrate, and a partial structure of the first gate line is used to form a gate electrode of the fourth transistor;
wherein an orthographic projection of the nineteenth active portion on the base substrate at least partially overlaps with the orthographic projection of the first gate line on the base substrate.

8. The display panel according to claim 7, wherein a maximum size of the orthographic projection of the nineteenth active portion on the base substrate in the first direction is larger than a maximum size of the orthographic projection of the nineteenth active portion on the base substrate in the second direction.

9. The display panel according to claim 8, wherein the maximum size of the orthographic projection of the nineteenth active portion on the base substrate in the first direction is L1, the maximum size of the orthographic projection of the nineteenth active portion on the base substrate in the second direction is L2, and L1/L2 is greater than or equal to 1.5 and less than or equal to 5.

10. The display panel according to claim 1, wherein the pixel driving circuit further includes a fourth transistor, a first electrode of the fourth transistor is connected to a data line, a second electrode of the fourth transistor is connected to a first electrode of the driving transistor, and a gate electrode of the fourth transistor is connected to a first gate line;
wherein a capacitance formed by an equipotential structure of the first conductive portion and an equipotential structure of the first gate line is C1, a capacitance formed by the equipotential structure of the first conductive portion and an equipotential structure of the second gate line is C2, and C1 is greater than C2.

11. The display panel according to claim 10, further comprising:
a second active portion used to form a channel region of the second transistor;
a nineteenth active portion connected to the second active portion, wherein an orthographic projection of the nineteenth active portion on the base substrate at least partially overlaps with an orthographic projection of the first gate line on the base substrate;
a fourth bridge portion, wherein the fourth bridge portion is connected to the nineteenth active portion and the first conductive portion through via holes respectively, and an orthogonal projection of the fourth bridge portion on the base substrate extends along a second direction and at least partially overlaps with the orthographic projection of the second gate line on the base substrate;
wherein an overlapping area of the orthographic projection of the nineteenth active portion on the base substrate and the orthographic projection of the first gate line on the base substrate is S1, and an overlapping area of the orthographic projection of the fourth bridge portion on the base substrate and the orthographic projection of the second gate line on the base substrate is S2;
wherein S1/S2 is greater than or equal to 1.2 and less than or equal to 2.

12. The display panel according to claim 1, wherein the display panel further comprises a light-emitting unit, the pixel driving circuit is used to drive the light-emitting unit to emit light, the pixel driving circuit further comprises a seventh transistor, a first electrode of the seventh transistor is connected to a second initialization signal line, and a second electrode of the seventh transistor is connected to a first electrode of the light-emitting unit;
wherein the display panel further comprises:
a fourth conductive layer located at a side of the base substrate, wherein the fourth conductive layer comprises the second initialization signal line;
wherein the second initialization signal line comprises a first initialization signal sub-line and a second initialization signal sub-line, an orthographic projection of the first initialization signal sub-line on the base substrate extends along the first direction, an orthographic projection of the second initialization signal sub-line on the base substrate extends along a second direction, and the second direction intersects the first direction;
wherein the first initialization signal sub-line is connected to the second initialization signal sub-line whose orthographic projection on the base substrate intersects the orthographic projection of the first initialization signal sub-line on the base substrate.

13. The display panel according to claim 1, wherein the pixel driving circuit further comprises a fifth transistor, a first electrode of the fifth transistor is connected to a power line, and a second electrode is connected to a first electrode of the driving transistor;
wherein the display panel further comprises:
a fourth conductive layer; and
a fifth conductive layer located at a side of the fourth conductive layer away from the base substrate, wherein the fifth conductive layer comprises the power line; and
wherein a first notch is formed in the power line, and the first notch is at least partially located in a light-transmitting region of the display panel.

14. The display panel according to claim 13, wherein an orthographic projection of the power line on the base substrate extends along a second direction, and the second direction intersects the first direction;
wherein the power line comprises a first power line segment, a second power line segment and a third power line segment, and the second power line segment is connected between the first power line segment and the third power line segment;
wherein a size of an orthographic projection of the second power line segment on the base substrate in the first direction is larger than a size of an orthogonal projection of the first power line segment on the base substrate in the first direction, the size of the orthographic projection of the second power line segment on the base substrate in the first direction is larger than a size of an orthogonal projection of the third power line segment on the base substrate in the first direction;
wherein the first notch comprises a first side and a second side, and an orthographic projection of the first side on the base substrate and an orthographic projection of the second side on the base substrate form an angle less than 90°;
wherein the first side is formed by a part of an edge of the second power line segment, and the second side is formed by a part of an edge of the first power line segment.

15. The display panel according to claim 1, wherein the pixel driving circuit further comprises a capacitor, a first electrode of the capacitor is connected to the gate electrode of the driving transistor, a second electrode of the capacitor is connected to a power line, and the first conductive portion is reused as the first electrode of the capacitor;
wherein the display panel further comprises:
a first conductive layer located at a side of the base substrate;
a second active layer located at a side of the first conductive layer away from the base substrate;
a second conductive layer located between the first conductive layer and the second active layer, wherein the second conductive layer comprises a-second conductive portions, an orthographic projection of one of the second conductive portions on the base substrate at least partially overlaps with the orthographic projection of the first conductive portion on the base substrate, and one of the second conductive portions is used to form the second electrode of the capacitor;
wherein at least a part of the second conductive portions adjacent in the first direction are connected.

16. The display panel according to claim 15, wherein the display panel comprises repeating units distributed in an array along the first direction and the second direction, the first direction intersects the second direction, and one of the repeating units comprises two pixel driving circuits distributed in the first direction, and two pixel driving circuits in a same repeating unit are arranged at least partially in mirror symmetry;
wherein the second conductive layer further comprises:
a first connection portion connected between two second conductive portions in a same repeating unit, and a size of an orthogonal projection of the first connection portion on the base substrate in the second direction is smaller than a size of an orthographic projection of one of the two second conductive portions on the base substrate in the second direction, and the first connection portion and the second conductive portions connected to the first connection portion form a third notch;
wherein an orthographic projection of the third notch on the base substrate at least partially overlaps with an orthographic projection of an equipotential structure of the second electrode of the driving transistor on the base substrate.

17. The display panel according to claim 15, wherein the display panel comprises repeating units distributed in an array along the first direction and the second direction, the first direction intersects the second direction intersect, one of the repeating units comprises two pixel driving circuits distributed in the first direction, and two pixel driving circuits in a same repeating unit are arranged at least partially in mirror symmetry;
wherein multiple second gate lines are connected to a same signal terminal;
wherein the second conductive layer further comprises:
a second connection portion connected between two adjacent second conductive portions in repeating units which are adjacent in the first direction, and a size of an orthographic projection of the second connection portion on the base substrate in the second direction is smaller than a size of an orthogonal projection of one of the second conductive portions on the base substrate in the second direction, and the second connection portion and the second conductive portions connected to the second connection portion form a second notch;
wherein an orthographic projection of the second notch on the base substrate at least partially overlaps with an orthographic projection of an equipotential structure of the first electrode of the driving transistor on the base substrate.

18. The display panel according to claim 1, wherein the display panel further comprises a light-emitting unit, the pixel driving circuit is used to drive the light-emitting unit to emit light, the pixel driving circuit further comprises a seventh transistor and an eighth transistor, a first electrode of the seventh transistor is connected to a second initialization signal line, a second electrode of the seventh transistor is connected to a first electrode of the light-emitting unit, a first electrode of the eighth transistor is connected to a third initialization signal line, and a second electrode of the eighth transistor is connected to a first electrode of the driving transistor;
wherein the display panel further comprises:
a first conductive layer located at a side of the base substrate, wherein the first conductive layer comprises a second reset signal line, an orthographic projection of the second reset signal line on the base substrate extends along the first direction, and a partial structure of the second reset signal line is used to form the gate electrode of the seventh transistor;
a third conductive layer located at a side of the first conductive layer away from the base substrate, wherein the third conductive layer comprises a third initialization signal line, and an orthographic projection of the third initialization signal line on the base substrate extends along the first direction;
wherein the orthographic projection of the second reset signal line on the base substrate at least partially overlaps with the orthographic projection of the third initialization signal line on the base substrate.

19. The display panel according to claim 1, wherein the display panel further comprises a light-emitting unit, the pixel driving circuit is used to drive the light-emitting unit to emit light, and the pixel driving circuit further comprises:
a fourth transistor, wherein a first electrode of the fourth transistor is connected to a data line, and a second electrode of the fourth transistor is connected to a first electrode of the driving transistor;
a fifth transistor, wherein a first electrode of the fifth transistor is connected to a power line, and a second electrode of the fifth transistor is connected to the first electrode of the driving transistor;
a sixth transistor, wherein a first electrode of the sixth transistor is connected to a second electrode of the driving transistor, and a second electrode of the sixth transistor is connected to a first electrode of the light-emitting unit;
a seventh transistor, wherein a first electrode of the seventh transistor is connected to a second initialization signal line, and a second electrode of the seventh transistor is connected to the first electrode of the light-emitting unit;
an eighth transistor, wherein a first electrode of the eighth transistor is connected to a third initialization signal line, and a second electrode of the eighth transistor is connected to the first electrode of the driving transistor; and
a capacitor connected between the gate electrode of the driving transistor and the power line;
wherein the display panel further comprises:
a first active layer, wherein the first active layer comprises a first active portion, a third active portion, a fourth active portion, a fifth active portion, a sixth active portion, a seventh active portion and an eighth active portion, the first active portion is used to form a channel region of the first transistor, the third active portion is used to form a channel region of the driving transistor, the fourth active portion is used to form a channel region of the fourth transistor, the fifth active portion is used to form a channel region of the fifth transistor, the sixth active portion is used to form a channel region of the sixth transistor, the seventh active portion is used to form a channel region of the seventh transistor, and the eighth active portion is used to form a channel region of the eighth transistor;
a first conductive layer located at a side of the first active layer away from the base substrate, wherein the first conductive layer comprises the first reset signal line, the first gate line, the second reset signal line, an enable signal line and the first conductive portion, a partial structure of the first gate line is used to form a gate electrode of the fourth transistor, a partial structure of the enable signal line is used to form gate electrodes of the fifth transistor and the six transistor, and a partial structure of the second reset signal line is used to form gate electrodes of the seventh transistor and the eighth transistor;
a second active layer located at a side of the first conductive layer away from the base substrate, wherein the second active layer comprises a second active portion, and the second active portion is used to form a channel region of the second transistor;
a third conductive layer located at a side of the second active layer away from the base substrate, wherein the third conductive layer comprises the second gate line;
wherein an orthographic projection of the enable signal line on the base substrate extends along the first direction and is located at a side of the orthographic projection of the first conductive portion on the base substrate away from the orthographic projection of the first reset signal line on the base substrate;
wherein the orthographic projection of the first gate line on the base substrate extends along the first direction and is located between the orthographic projection of the second gate line on the base substrate and the orthographic projection of the first reset signal line on the base substrate;
wherein the orthographic projection of the second reset signal line on the base substrate extends along the first direction and is located at a side of the orthographic projection of the enable signal line on the base substrate away from the orthographic projection of the first conductive portion on the base substrate.

20. (canceled)

21. A display device, wherein the display device comprises a display panel;
wherein the display panel comprises:
a pixel driving circuit, wherein the pixel driving circuit comprises a driving transistor, a first transistor and a second transistor, a first electrode of the second transistor is connected to a gate electrode of the driving transistor, a second electrode of the second transistor is connected to a second electrode of the driving transistor, a first electrode of the first transistor is connected to a first initialization signal line, and a second electrode of the first transistor is connected to the second electrode of the second transistor;
wherein the display panel further comprises:
a base substrate;
a first reset signal line, wherein an orthographic projection of the first reset signal line on the base substrate extends along a first direction, and a partial structure of the first reset signal line is used to form a gate electrode of the first transistor;
a second gate line, wherein an orthographic projection of the second gate line on the base substrate extends along the first direction, and a partial structure of the second gate line is used to form a gate electrode of the second transistor;
a first conductive portion, wherein the first conductive portion is used to form the gate electrode of the driving transistor:
wherein the orthographic projection of the second oate line on the base substrate is Located between the orthographic projection of the first reset signal line on the base substrate and an orthographic projection of the first conductive portion on the base substrate.
